(19) United States
(12) Patent Application Publication
(10) Pub. No.: US 2026/0165218 A1
(43) Pub. Date: Jun. 11, 2026

(54) SUBSTRATE ASSEMBLY AND ASSEMBLY PACKAGE

(71) Applicant: PanelSemi Corporation, New Taipei City (TW)

(72) Inventors: Chin-Tang LI, New Taipei City (TW); HSIEN-TE CHEN, New Taipei City (TW); Pen-Chao LO, New Taipei City (TW)

(21) Appl. No.: 19/415,536

(22) Filed: Dec. 10, 2025

Related U.S. Application Data
(60) Provisional application No. 63/730,135, filed on Dec. 10, 2024.
(60) Provisional application No. 63/794,567, filed on Apr. 25, 2025.

(51) Int. Cl. H10W 90/00; H10W 70/63; H10W 70/652; H10W 70/67

(52) U.S. Cl. CPC H10W 90/401; H10W 70/63; H10W 70/652; H10W 70/688

(57) ABSTRACT

A substrate assembly is disclosed, comprising a carrier board defining a planar direction and a plurality of substrates adjacently arranged thereon. Each substrate has opposite first and second surfaces, with a temporary adhesive layer bonding the second surface to the carrier board. A functional material fills the gaps between adjacent substrates. The carrier board's area is no less than the total area of the substrates. Crucially, in a direction perpendicular to the planar direction, the height difference between the first surfaces or the second surfaces of adjacent substrates is controlled to be no greater than 50μm. This structure ensures precise alignment and stability for subsequent processing.

### CROSS REFERENCE TO RELATED APPLICATIONS

This Non-provisional application which claims priority under 35 U.S.C. § 119(a) on patent application Ser. No(s). 63/730,135 filed in United States of America on Dec. 10, 2024, and on patent application Ser. No(s). 63/794,567 filed in United States of America on Apr. 25, 2025, the entire contents of which are hereby incorporated by reference.

### BACKGROUND

### Technology Field

The present invention relates to a substrate assembly that can be applied to electronic packaging, and more particularly to a substrate assembly for semiconductor packaging and its assembly package.

### Description of Related Art

With the trend towards miniaturization, high performance, and high integration in electronic products, the requirements for substrate assemblies are becoming increasingly demanding. However, traditional substrate manufacturing processes face a plurality of challenges. For instance, to achieve cost reduction, a considerable scale of manufacturing is required, which leads to the need for large-sized substrates. However, the fabrication of large-sized substrates presents difficulties, particularly in ensuring surface flatness, where technical bottlenecks exist. Furthermore, during subsequent processes (such as packaging processes), differences in thermal expansion coefficients between materials can easily cause warpage deformation of the substrate assembly, thereby affecting product yield. In existing technology, a common approach is to use single-sized substrates for processing, but this method cannot effectively reduce manufacturing costs.

### SUMMARY

One aspect of the present invention is to provide a substrate assembly and one or more exemplary embodiments thereof, all of which demonstrate that this substrate assembly is a mosaic-style large-sized composite substrate that can effectively reduce manufacturing costs.

One aspect of the present invention is to provide a substrate assembly and one or more exemplary embodiments thereof, all of which demonstrate that this substrate assembly is a mosaic-style large-sized composite substrate that maintains surface planarity while being compatible with subsequent processing applications.

One aspect of the present invention is to provide an assembly package and one or more exemplary embodiments thereof, all of which illustrate a substrate assembly of this tiled large-sized composite substrate, which can be adapted to the assembly package through dicing or size reduction.

The present invention is to provide a substrate assembly includes a carrier board, a plurality of substrates, a temporary adhesive layer, and a functional material. The carrier board defines a planar direction, and the plurality of substrates are adjacently arranged on the carrier board in the planar direction. Each of the substrates has opposing first and second surfaces. The temporary adhesive layer is arranged between the second surface of the substrates and the carrier board, while the functional material fills a gap between adjacent two of the substrates. The carrier board of the present invention has a planar area not less than twice of a planar area of each of the substrates, enabling it to accommodate a plurality of substrates being supported thereon. Furthermore, a height difference is defined along a direction perpendicular to the planar direction between the first surfaces of adjacent two of the substrates, and/or a height difference is defined along a direction perpendicular to the planar direction between the second surfaces of adjacent two of the substrates, wherein this height difference does not exceed 50 micrometers. the substrates define a height up to the first surfaces in a direction perpendicular to the planar direction, with the height difference between adjacent two of the substrates not exceeding 10 micrometers, thereby maintaining a flatness of a virtual surface collectively defined by the first surfaces of these substrates tiled with one another or/and the second surfaces of these substrates on the carrier board.

In some embodiments, the carrier board and/or the substrates include Si, silica (SiO₂), glass, quartz, silicon carbide, ceramics, glass-ceramic, sapphire (Al₂O₃), compound semiconductor material, or polyimide, or any combination including one or more of the aforementioned materials.

In some embodiments, the carrier board defines a coefficient of thermal expansion not greater than 15 ppm/K within a temperature range from 25° C. to 400° C.

The planar area of the carrier board in the planar direction is not less than 16000 mm².

In some embodiments, the planar area is not less than 17000 mm².

In some embodiments, the planar area is not less than 90000 mm².

In some embodiments, the carrier board defines a planar area in the planar direction not less than 170000 mm².

In some embodiments, the carrier board defines a planar area in the planar direction not less than 250000 mm².

In some embodiments, a height difference is defined between the first surfaces of adjacent two of the substrates, and/or between the second surfaces of adjacent two of the substrates, and the height difference is not greater than 10 μm.

In some embodiments, a maximum thickness of the temporary adhesive layer is not less than the height difference between the second surfaces of adjacent two of the substrates.

In some embodiments, a maximum thickness of the temporary adhesive layer is not less than a flatness of the second surface of adjacent one of the substrates.

In some embodiments, each of the substrates defines a flatness of not more than 10 μm on the first surface or the second surface.

In some embodiments, the flatness is not more than 3 μm.

In some embodiments, the planar area of the carrier board is not less than twice of a planar area of the substrates.

In some embodiments, the carrier board defines a thickness not greater than 1 mm.

In some embodiments, the substrates defines a coefficient of thermal expansion not greater than 15 ppm/K within a temperature range from 25° C. to 400° C.

In some embodiments, the substrate assembly further defines a difference in coefficient of thermal expansion between the substrates and the carrier board, and the difference in coefficient of thermal expansion is not greater than 12 ppm/K within the temperature range.

In some embodiments, the substrate assembly further defines a difference in coefficient of thermal expansion between the substrates and the carrier board, and the difference in coefficient of thermal expansion is not greater than 8 ppm/K within the temperature range.

In some embodiments, the difference in coefficient of thermal expansion is not greater than 5 ppm/K within the temperature range.

In some embodiments, each of the substrates is a multi-layer substrate, including a glass material, a glass-ceramic material, or a ceramic material, and a polyimide material bonded to the aforementioned material; wherein a difference in coefficient of thermal expansion is defined between the polyimide material and the glass material/glass-ceramic material/ceramic material, and this difference in coefficient of thermal expansion is not greater than 5 ppm/K within a temperature range of 25° C.˜400° C.

In some embodiments, each of the substrates defines a thermal conductivity coefficient not less than 1.0 W/m*K.

In some embodiments, the thermal conductivity coefficient is not less than 2.0 W/m*K.

In some embodiments, each of the substrates defines an elastic modulus not less than 50 GPa.

In some embodiments, the elastic modulus is not less than 80 GPa.

In some embodiments, the temporary adhesive layer defines a debonding temperature not less than 200° C.

In some embodiments, the temporary adhesive layer defines a debonding wavelength band that absorbs a predetermined band of wavelengths.

In some embodiments, the functional material defines an elastic modulus less than an elastic modulus of an adjacent one of the substrates.

In some embodiments, the substrate assembly further includes a first electrical layer structure arranged on the first surface of each of the substrates.

In some embodiments, the first electrical layer structure extends upon the functional material adjacent to a corresponding one of the substrates.

In some embodiments, each of the substrates include one or more conductive vias.

In some embodiments, the substrate assembly further includes one or more holes, configured to each of the substrates and communicating with at least one of the first and second surfaces.

In some embodiments, the holes communicate with the first surface and the second surface thereof for forming one or more through holes.

In some embodiments, the functional material is at least arranged in one or ones of the holes of each of the substrates.

In some embodiments, the substrate structure further includes one or more inner holes configured to the functional material and respectively located within the corresponding one or ones of the holes.

In some embodiments, one or ones of the holes in each of the substrates are formed at or before the substrates allocate on the carrier board.

In some embodiments, the substrate structure further includes a second electrical layer structure arranged between the temporary adhesive layer and the second surface of each of the substrates.

In some embodiments, the second electrical layer structure extends to the functional material arranged between adjacent two of the substrates.

In some embodiments, the second electrical layer structure is a non-patterned electrical layer structure.

In some embodiments, the height difference between the first surfaces of adjacent two of the substrates is not greater one-tenth of a thickness of adjacent one of the substrates.

In some embodiments, the first surfaces of the substrates collectively define a polished surface, wherein the polished surface is formed by polishing performed at the same time.

In some embodiments, the second surfaces of the substrates collectively define a polished surface, wherein the polished surface is formed by polishing performed at the same time.

In some embodiments, the substrate assembly further includes a first electrical layer structure and a second electrical layer structure, wherein the first electrical layer structure is arranged on the first surface of each of the substrates, the second electrical layer structure is arranged between the temporary adhesive layer and the second surface of each of the substrates; each of the substrates include one or more conductive vias electrically connecting the first electrical layer structure and the second electrical layer structure.

In some embodiments, the substrate assembly further includes a feeding board electrically connected to the second electrical layer structure; wherein the feeding board includes a conductive via electrically connected to the second electrical layer structure.

In some embodiments, the feeding board is adjacent to the edge of a corresponding one of the substrates.

In some embodiments, the conductive via is formed by sintered.

In some embodiments, one of the substrates defines a feeding area, which electrically connected to the second electrical layer structure.

In some embodiments, the corresponding one of the substrates defines a conductive via at the feeding area, and the conductive via electrically connected to the second electrical layer structure.

In some embodiments, one or ones of the substrates defines a bending strength not less than 150 MPa (Megapascal).

In some embodiments, one or ones of the substrates a dielectric loss Df (Loss Tangent) not greater than 0.006 at a test frequency of 10 GHz (Gigahertz).

In some embodiments, the substrate assembly further defines a plurality of cutting units, wherein each of the cutting units is free of the gap.

In some embodiments, the substrate assembly further includes one or more marks, wherein the mark or marks are configured with the carrier substrate.

In some embodiments, the mark or marks are located, along the vertical direction, within a projection range of one of the substrates on the carrier substrate.

In some embodiments, the substrate or substrates are light-transmissive.

In some embodiments, the substrate assembly further includes one or more counter marks, wherein the counter mark or counter marks are configured with the substrates.

In some embodiments, each of the substrate defines one or more the corners or edges, and one of the substrates defines a chamfer at one or ones of the corners or edges.

In some embodiments, the functional material wrapping one or ones of the corners or edges of one or ones of the substrates.

The present invention is to provide an assembly package, comprising: a portion of the substrate assembly mentioned above, wherein a part of the substrate assembly is removed from the temporary adhesive layer and the carrier board and further defines a plurality of cutting units, each of the cutting units is free of the gap, and the portion of the assembly package includes one or ones of the cutting units; wherein a size of each of the cutting units is greater than or equal to a size of one of the substrates, referred in the substrate assembly mentioned above.

In some embodiments, a size of each of the cutting units approaches a size of one of the substrates.

In some embodiments, each of the substrate defines one or more corners or edges, and one of the substrates defines a chamfer at one or more corners or edges.

In some embodiments, the functional material wrapping one or ones of the corners or edges of one or ones of the substrates.

The present invention is to provide an assembly package, comprising a portion of a substrate assembly combination; wherein the substrate assembly combination includes two substrate assemblies mentioned above, the two substrate assemblies bonded with each other, and a conductive via at least electrically connecting the first electrical layer structures of the two substrate assemblies; wherein the portion of the substrate assembly combination, removed from the temporary adhesive layer and the carrier board, defines a plurality of cutting units, and each of the cutting units is free of the gap; the portion of the assembly package combination includes the cutting unit or the cutting units, wherein a size of each of the cutting units is greater than or equal to a size of one of the substrates, referred in the substrate assembly mentioned above.

In some embodiments, a size of each of the cutting units approaches a size of one of the substrates.

In some embodiments, each of the substrate defines one or more corners or edges, and one of the substrates defines a chamfer at one or more corners or edges.

In some embodiments, the functional material wrapping one or ones of the corners or edges of one or ones of the substrates.

In some embodiments, the assembly package further includes a bonding layer the two substrate assemblies together.

The present invention is to provide an assembly package, comprising: a substrate defining a first surface and a second surface corresponding to each other, a plurality of corners or edges, one or more chamfers, and a plurality of conductive holes; and a functional material arranged on at least a portion of the first surface and second surface of the substrate, and the corners or edges; wherein the conductive holes communicate with at least one surface of the first and second surfaces of each substrate.

In some embodiments, one of ones of the chamfers is/are defined corresponding one or ones of the corners or edges.

In some embodiments, the functional material wrapping one or ones of the corners or edges of one or ones of the substrates.

In some embodiments, the functional material arranged on at least one surface of the first and the second surfaces of one or ones of the substrates.

In some embodiments, one or ones of the conductive hole holes communicate(s) with the at least one of an outmost surface of the functional material.

In some embodiments, the functional material includes one or more sub-functional material(s).

In some embodiments, one or ones of the conductive hole holes communicate(s) with the at least one of the first and second surfaces of each of the substrates.

In some embodiments, the assembly package further includes one or more holes, configured to each of the substrates and communicating with at least one of the first and second surfaces.

In some embodiments, the functional material is at least arranged in one or ones of the holes of each of the substrates.

In some embodiments, the assembly package further includes one or more inner holes configured to the functional material and respectively located within the corresponding one or ones of the holes to form the conductive holes.

The present invention is to provide an assembly package, comprising: two substrates arranged opposite to and bonded to each other; wherein each substrate defines a first surface and a second surface corresponding to each other, a plurality of corners or edges, one or more chamfers, and a plurality of conductive holes; and one or more functional materials, arranged on at least the first surface and second surface of the substrate, and at least a portion of those corners or edges; wherein at least a portion of the conductive holes of one substrate are electrically connected to at least a portion of the conductive holes of another substrate; wherein the conductive holes communicate with at least one surface of the first and second surfaces of each substrate.

In some embodiments, the assembly package further includes a bonding layer connecting the first surface of one substrate with the second surface of another substrate.

In some embodiments, the chamfer or chamfers define one or ones of the corners or edges.

In some embodiments, the functional material wraps one or ones of the corners or edges of one or ones of the substrates.

In some embodiments, the functional material covers one or both of the first and second surfaces of each of the substrates.

In some embodiments, one or ones of the conductive hole holes communicate(s) with the at least one of an outmost surface of the functional material.

In some embodiments, the functional material includes one or more sub-functional material(s).

In some embodiments, one or ones of the conductive hole holes communicate(s) with the at least one of the first and second surfaces of each of the substrates.

In some embodiments, the assembly package further includes one or more holes, configured to each of the substrates and communicating with at least one of the first and second surfaces.

In some embodiments, the functional material is at least arranged in one or ones of the holes of each of the substrates.

In some embodiments, the assembly package further includes one or more inner holes configured to the functional material and respectively located within the corresponding one or ones of the holes to form the conductive holes.

The foregoing is merely illustrative and not intended to limit the present invention. In addition to the illustrative embodiments, examples, and features described above, other embodiments, examples, and features of the present invention can be clearly understood by referring to the drawings and the following detailed description.

### BRIEF DESCRIPTION OF THE DRAWINGS

FIG. 1 is a top view of a substrate assembly according to one embodiment of the present disclosure.

FIG. 1A is a side view of FIG. 1.

FIG. 1AX is a side view of another embodiment of the substrate assembly of the present disclosure, illustrating a height difference between adjacent substrates.

FIG. 1B is a side view of another embodiment of the substrate assembly of the present disclosure, illustrating a segmented temporary adhesive layer.

FIG. 1C is a side view of another embodiment of the substrate assembly of the present disclosure, illustrating an aspect of the substrate structure.

FIG. 1D is a side view of another embodiment of the substrate assembly of the present disclosure, illustrating an aspect of the carrier board.

FIG. 1E is a side view of another embodiment of the substrate assembly of the present disclosure, illustrating an aspect of the functional material.

FIG. 1FA is a side view of another embodiment of the substrate assembly of the present disclosure, illustrating an aspect of the functional material structure.

FIG. 1FB is a side view of another embodiment of the substrate assembly of the present disclosure, illustrating another aspect of the functional material structure.

FIG. 1G is a side view of another embodiment of the substrate assembly of the present disclosure, illustrating yet another aspect of the functional material structure.

FIG. 1GA is a side view of another embodiment of the substrate assembly of the present disclosure, illustrating still another aspect of the functional material structure.

FIG. 1GB is a side view of another embodiment of the substrate assembly of the present disclosure, illustrating a further aspect of the functional material structure.

FIG. 1GM is a side view of another embodiment of the substrate assembly of the present disclosure, illustrating one of various aspects of the functional material structure.

FIG. 1GN is a side view of another embodiment of the substrate assembly of the present disclosure, illustrating one of various aspects of the functional material structure.

FIG. 1H is a side view of another embodiment of the substrate assembly of the present disclosure, illustrating one of various arrangements of the substrate and the functional material.

FIG. 1HA is a side view of another embodiment of the substrate assembly of the present disclosure, illustrating one of various arrangements of the substrate and the functional material.

FIG. 1HB is a side view of another embodiment of the substrate assembly of the present disclosure, illustrating one of various arrangements of the substrate and the functional material.

FIG. 1HC is a side view of another embodiment of the substrate assembly of the present disclosure, illustrating one of various arrangements of the substrate and the functional material.

FIG. 1HD is a side view of another embodiment of the substrate assembly of the present disclosure, illustrating one of various arrangements of the substrate and the functional material.

FIG. 1IA is a side view of another embodiment of the substrate assembly of the present disclosure, illustrating one of various aspects including an electrical layer structure.

FIG. 1IB is a side view of another embodiment of the substrate assembly of the present disclosure, illustrating one of various aspects including an electrical layer structure.

FIG. 1IC is a side view of another embodiment of the substrate assembly of the present disclosure, illustrating one of various aspects including an electrical layer structure.

FIG. 1IP is a side view of another embodiment of the substrate assembly of the present disclosure, illustrating one of various aspects including an electrical layer structure.

FIG. 1IQ is a side view of another embodiment of the substrate assembly of the present disclosure, illustrating one of various aspects including an electrical layer structure.

FIG. 1IR is a side view of another embodiment of the substrate assembly of the present disclosure, illustrating one of various aspects including an electrical layer structure.

FIG. 1JA is a side view of another embodiment of the substrate assembly of the present disclosure, illustrating one of various aspects including an electrical layer structure.

FIG. 1JB is a side view of another embodiment of the substrate assembly of the present disclosure, illustrating one of various aspects including an electrical layer structure.

FIG. 1K is a side view of another embodiment of the substrate assembly of the present disclosure, illustrating one of various aspects of a chamfer.

FIG. 1KA is a side view of another embodiment of the substrate assembly of the present disclosure, illustrating one of various aspects of a chamfer.

FIG. 1KB is a side view of another embodiment of the substrate assembly of the present disclosure, illustrating one of various aspects of a chamfer.

FIG. 1L is a side view of another embodiment of the substrate assembly of the present disclosure, illustrating one of various aspects of a chamfer.

FIG. 1MA is a side view of another embodiment of the substrate assembly of the present disclosure, illustrating one of various aspects of a chamfer.

FIG. 1MB is a side view of another embodiment of the substrate assembly of the present disclosure, illustrating one of various aspects of a chamfer.

FIG. 1MC is a side view of another embodiment of the substrate assembly of the present disclosure, illustrating one of various aspects of a chamfer.

FIG. 1MM is a side view of another embodiment of the substrate assembly of the present disclosure, illustrating one of various aspects of a chamfer.

FIG. 1MN is a side view of another embodiment of the substrate assembly of the present disclosure, illustrating one of various aspects of a chamfer.

FIG. 1MP is a side view of another embodiment of the substrate assembly of the present disclosure, illustrating one of various aspects of a chamfer.

FIG. 1MQ is a side view of another embodiment of the substrate assembly of the present disclosure, illustrating one of various aspects of a chamfer.

FIG. 1MR is a side view of another embodiment of the substrate assembly of the present disclosure, illustrating one of various aspects of a chamfer.

FIG. 1NA is a side view of another embodiment of the substrate assembly of the present disclosure, illustrating one of various aspects of a chamfer.

FIG. 1NB is a side view of another embodiment of the substrate assembly of the present disclosure, illustrating one of various aspects of a chamfer.

FIG. 1NC is a side view of another embodiment of the substrate assembly of the present disclosure, illustrating one of various aspects of a chamfer.

FIG. 1O is a side view of another embodiment of the substrate assembly of the present disclosure, illustrating one of various aspects of an electrical layer.

FIG. 1OM is a side view of another embodiment of the substrate assembly of the present disclosure, illustrating one of various aspects of an electrical layer.

FIG. 1ON is a side view of another embodiment of the substrate assembly of the present disclosure, illustrating one of various aspects of an electrical layer.

FIG. 1OP is a side view of another embodiment of the substrate assembly of the present disclosure, illustrating one of various aspects of an electrical layer.

FIG. 1OQ is a side view of another embodiment of the substrate assembly of the present disclosure, illustrating a step in one of various aspects of forming an electrical layer or a via.

FIG. 1OX is a side view of another embodiment of the substrate assembly of the present disclosure, illustrating a step in one of various aspects of forming an electrical layer or a via.

FIG. 1OY is a side view of another embodiment of the substrate assembly of the present disclosure, illustrating a step in one of various aspects of forming an electrical layer or a via.

FIG. 1P is a side view of another embodiment of the substrate assembly of the present disclosure, illustrating another aspect of forming an electrical layer.

FIG. 1PX is a side view of another embodiment of the substrate assembly of the present disclosure, illustrating another aspect of forming an electrical layer.

FIG. 1Q is a side view of another embodiment of the substrate assembly of the present disclosure, illustrating another aspect of forming an electrical layer and a feeding board.

FIG. 1QX is a side view of another embodiment of the substrate assembly of the present disclosure, illustrating another aspect of forming an electrical layer and a feeding board.

FIG. 1QY is a side view of another embodiment of the substrate assembly of the present disclosure, illustrating another aspect of forming an electrical layer and a feeding board.

FIG. 1R is a side view of another embodiment of the substrate assembly of the present disclosure, illustrating another aspect of forming an electrical layer and a feeding board.

FIG. 1S is a side view of another embodiment of the substrate assembly of the present disclosure, illustrating another aspect of forming an electrical layer and a feeding board.

FIG. 1T is a side view of another embodiment of the substrate assembly of the present disclosure, illustrating another aspect of forming an electrical layer and a feeding board.

FIG. 1U is a side view of another embodiment of the substrate assembly of the present disclosure, illustrating another aspect of forming an electrical layer and a feeding area.

FIG. 1UM is a side view of another embodiment of the substrate assembly of the present disclosure, illustrating another aspect of forming an electrical layer and a feeding area.

FIG. 1UX is a side view of another embodiment of the substrate assembly of the present disclosure, illustrating another aspect of forming an electrical layer and a feeding area.

FIG. 1UY is a side view of another embodiment of the substrate assembly of the present disclosure, illustrating another aspect of forming an electrical layer and a feeding area.

FIG. 1V is a side view of another embodiment of the substrate assembly of the present disclosure, illustrating another aspect of forming an electrical layer and a feeding area.

FIG. 1W is a side view of another embodiment of the substrate assembly of the present disclosure, illustrating another aspect of forming an electrical layer and a feeding area.

FIG. 1WA is a side view of another embodiment of the substrate assembly of the present disclosure, illustrating another aspect of forming an electrical layer and a feeding area.

FIG. 1WB is a side view of another embodiment of the substrate assembly of the present disclosure, illustrating another aspect of forming an electrical layer and a feeding area.

FIG. 1X is a side view of another embodiment of the substrate assembly of the present disclosure, illustrating yet another aspect of forming a multi-layer electrical layer.

FIG. 1XA is a side view of another embodiment of the substrate assembly of the present disclosure, illustrating yet another aspect of forming a multi-layer electrical layer.

FIG. 1XB is a side view of another embodiment of the substrate assembly of the present disclosure, illustrating yet another aspect of forming a multi-layer electrical layer.

FIG. 2 is a side view of one embodiment of the substrate assembly of the present disclosure removed from the carrier board.

FIG. 2A is a view of one of the cutting units of the present disclosure.

FIG. 2AX is a view of another one of the cutting units of the present disclosure.

FIG. 2W is a side view of FIG. 2, tiled on the carrier board with cutting units defined.

FIG. 2X is a side view of another embodiment of the substrate assembly of the present disclosure removed from the carrier board.

FIG. 2XW is a side view of FIG. 2X, tiled on the carrier board with cutting units defined.

FIG. 3 is a side view of a multi-layer embodiment of the substrate assembly of the present disclosure.

FIG. 3A is a side view of another embodiment of FIG. 3.

FIG. 3B is a side view of yet another embodiment of FIG. 3.

FIG. 3X is a side view of a step in forming FIG. 3.

FIG. 3Y is a side view of another step in forming FIG. 3.

FIG. 4 is a side view of one embodiment of the substrate assembly of FIG. 3 removed from the carrier board.

FIG. 4A is a side view of the cutting unit of FIG. 4 disposed on an electrical board.

FIG. 4AX is a side view of another cutting unit of FIG. 4 disposed on an electrical board.

FIG. 5 is a side view of one embodiment of a substrate assembly of the present disclosure removed from the carrier board.

FIG. 5A is a side view of the cutting unit of FIG. 5 disposed on an electrical board.

FIG. 5AX is a side view of another cutting unit of FIG. 5 disposed on an electrical board.

FIG. 6 is a top view of FIG. 2 provided with marks and corresponding mark configurations.

### DETAILED DESCRIPTION OF THE DISCLOSURE

The following description will refer to relevant drawings to explain the substrate assembly according to the preferred embodiments of this invention, wherein the same elements will be described using the same reference symbols.

The advantages, features, and implementation methods of the present invention will be clearly explained in the following embodiments with reference to the drawings. However, the present invention may be embodied in various forms and should not be construed as being limited to the embodiments described herein. Rather, these embodiments are provided to make this specification thorough and complete, and to fully convey the scope of the disclosure to those skilled in the art. The scope of the present invention should be defined only by the appended claims. Therefore, well-known components, operations, and techniques are not described in detail in the embodiments to avoid obscuring the technical features of the disclosure. Throughout the specification, identical or similar elements are denoted by identical or similar reference symbols. When an element is referred to as being “connected” to another element, it may be “directly or indirectly mechanically connected” to, or “electrically connected” to the other element, and one or more intervening elements may be present therebetween. It is to be understood that in this specification, the terms “include” or “comprise” specify the stated features, integers, steps, operations, elements and/or components, but do not preclude the presence or addition of one or more other features, integers, steps, operations, elements and/or components, or any combination thereof. The term “and/or” or “or/and” indicates the possibility of intersection or union of one or more other features, integers, steps, operations, elements and components, or any combination thereof. Unless otherwise defined, all terms used in this specification (including technical and scientific terms) have the same meanings as commonly understood by those skilled in the art to which the present invention pertains. Further, terms, including those defined in commonly used dictionaries, should be interpreted as having meanings consistent with their meaning in the context of the relevant art and will not be interpreted in an idealized or overly rigorous sense unless explicitly defined herein.

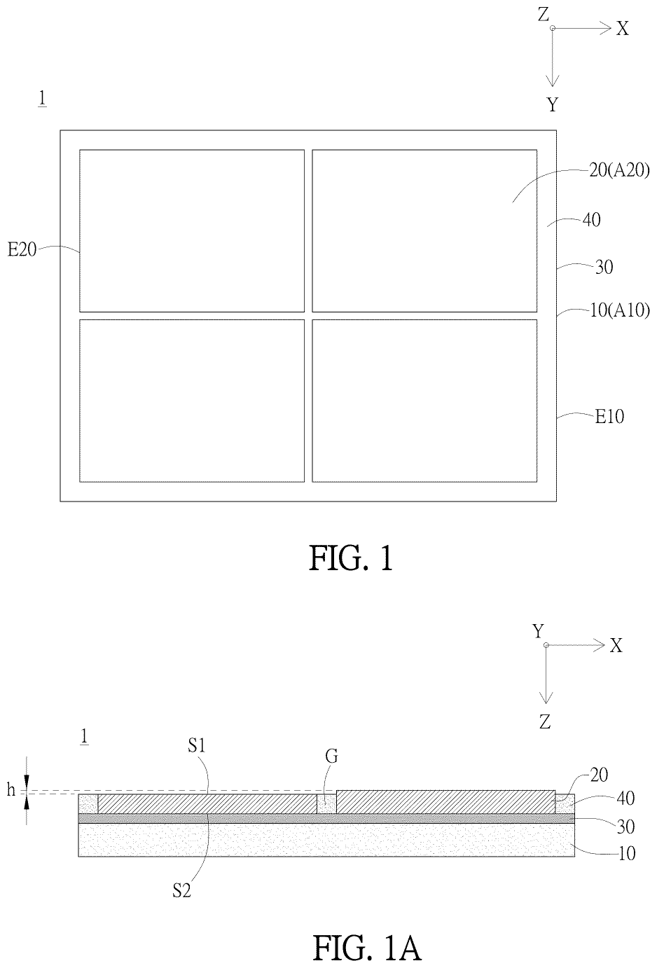

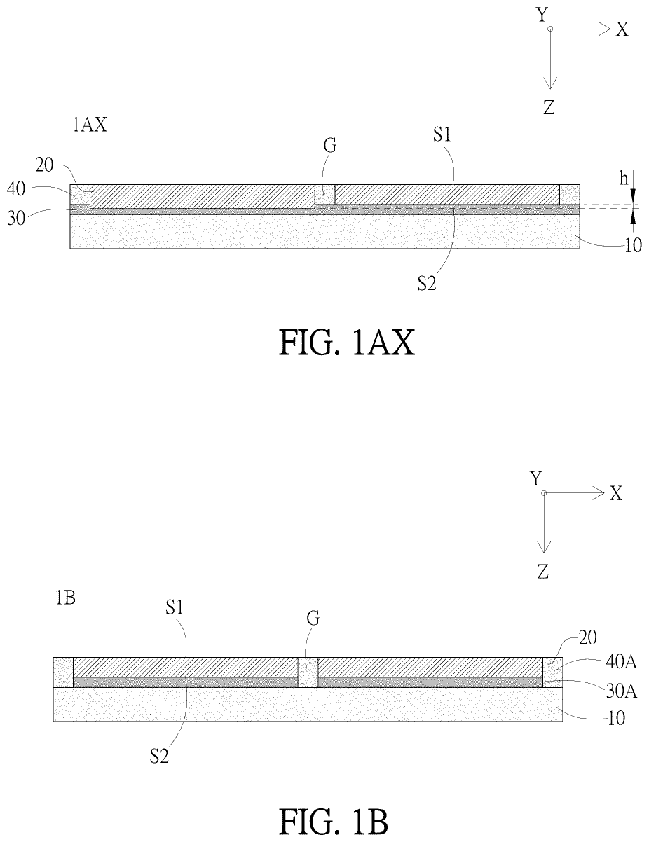

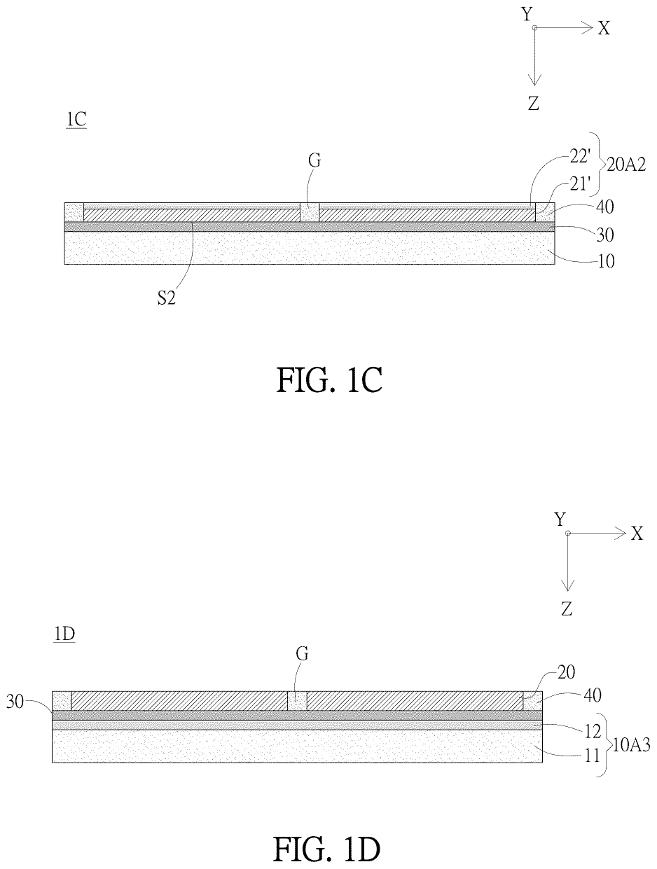

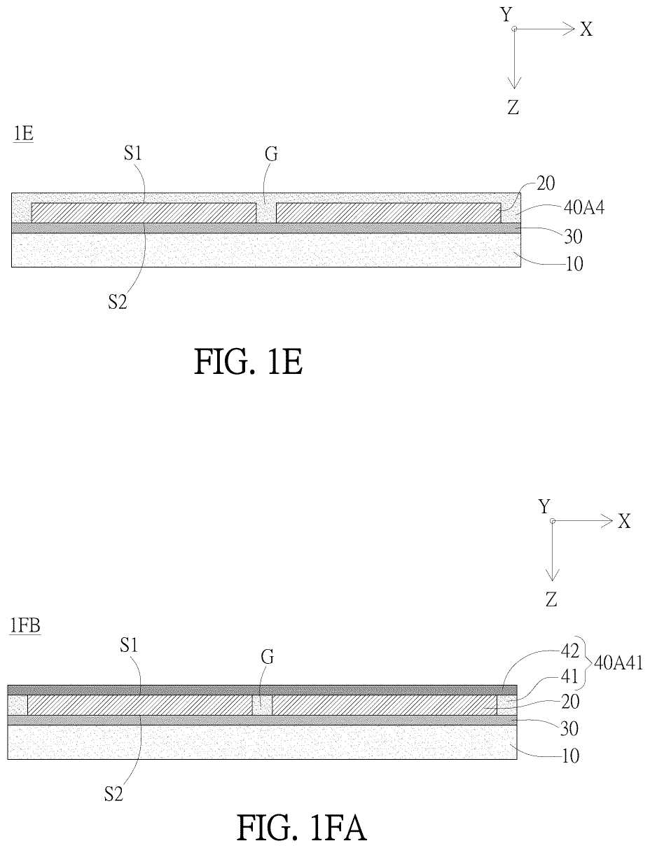

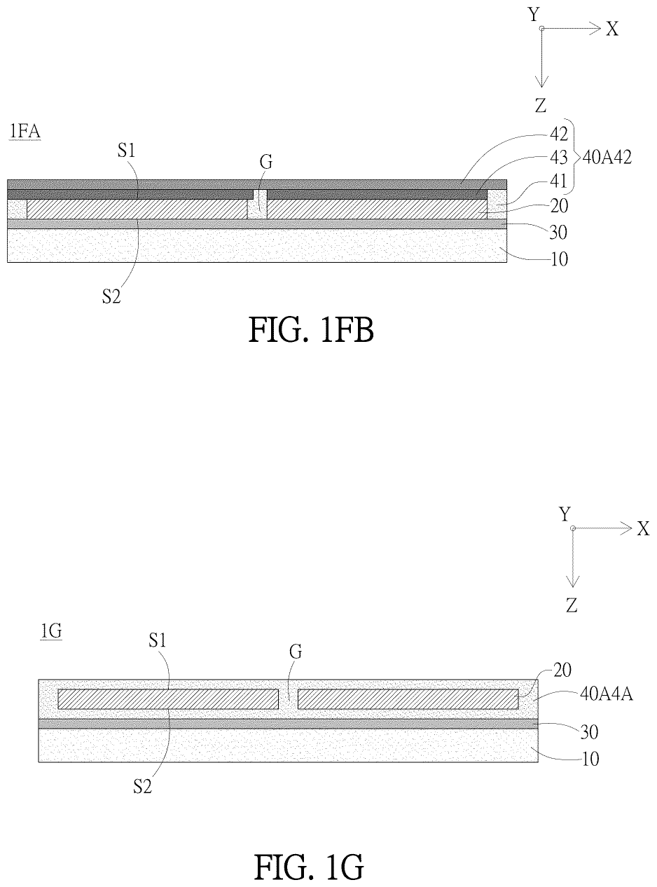

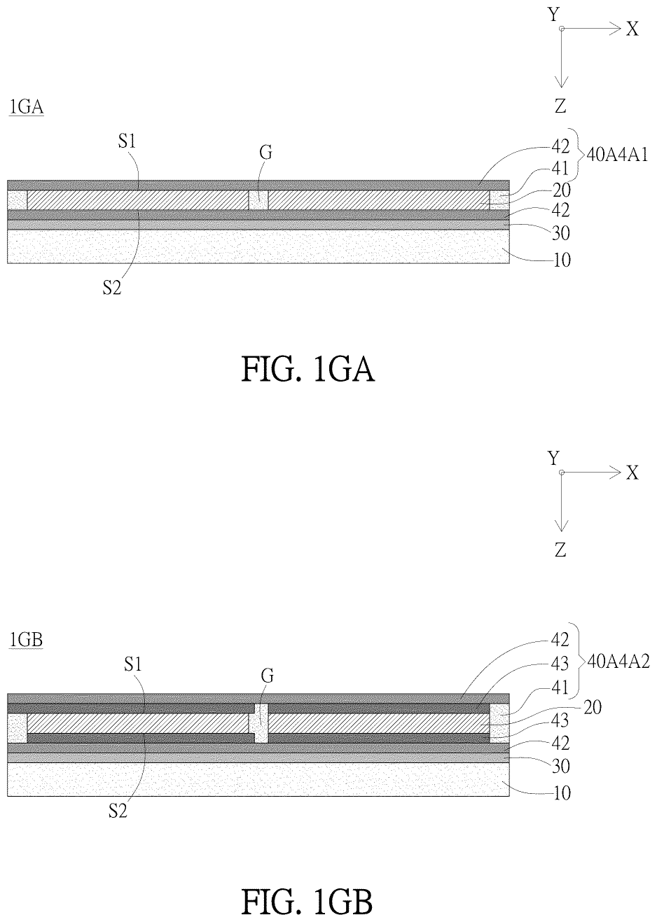

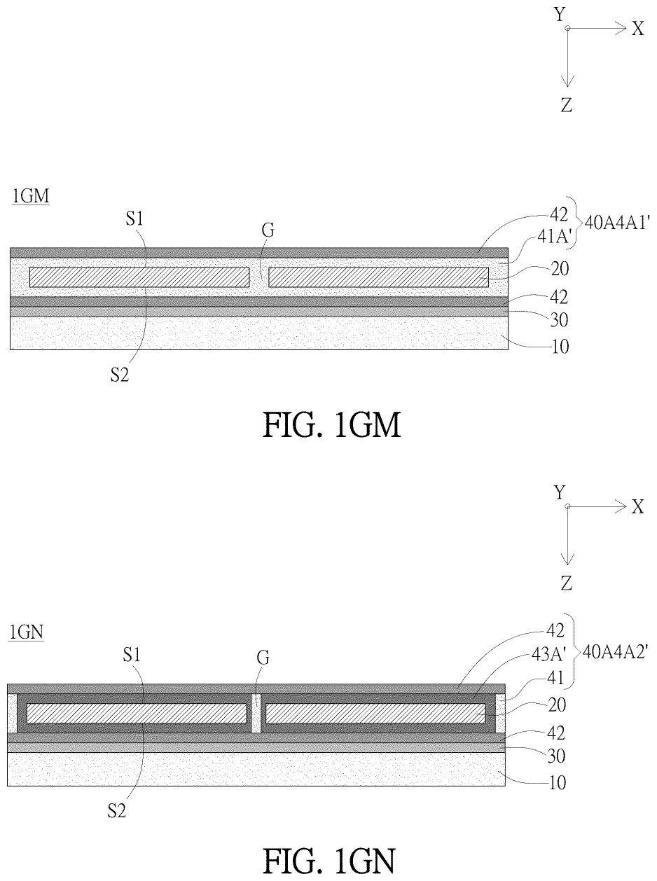

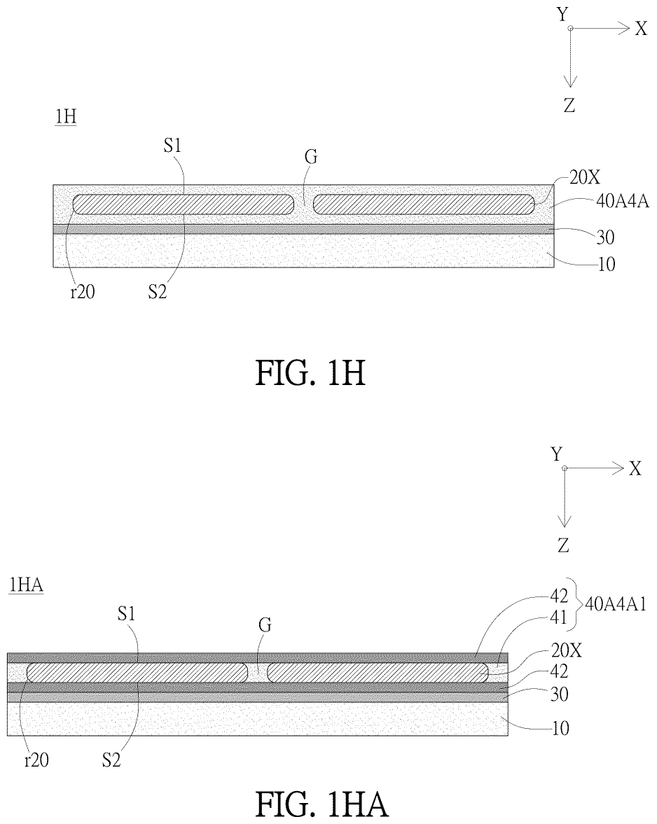

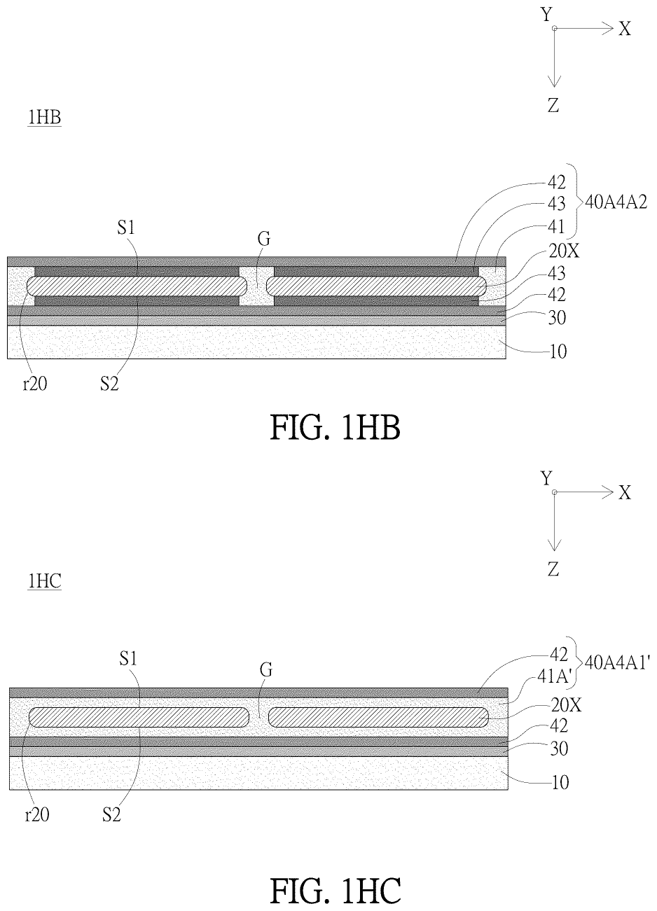

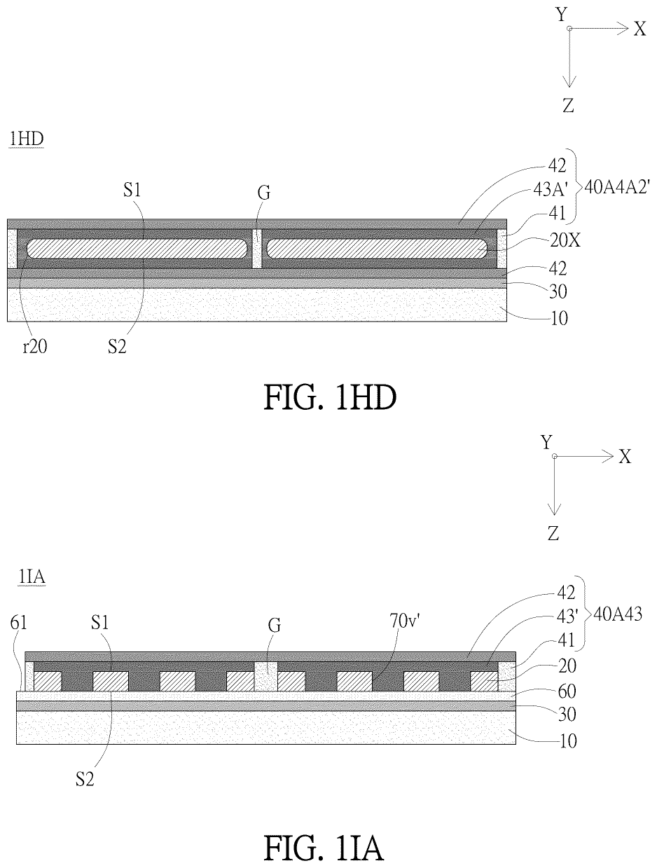

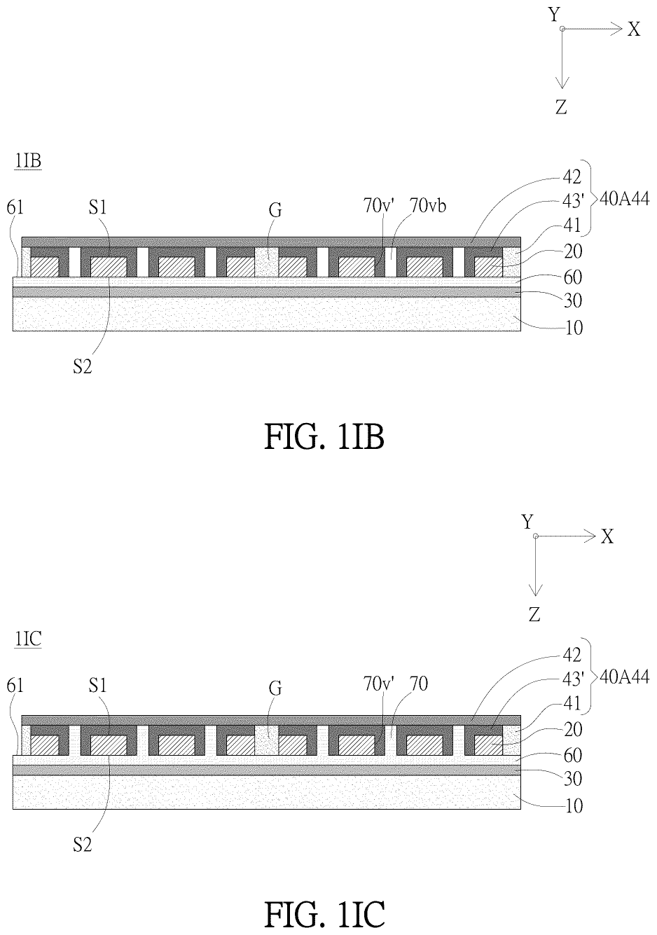

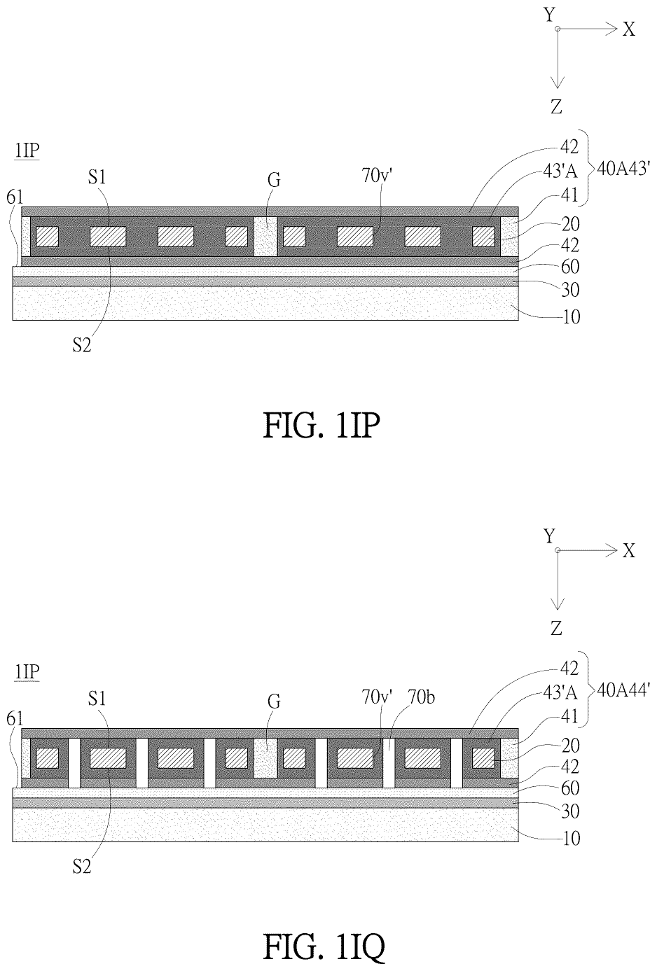

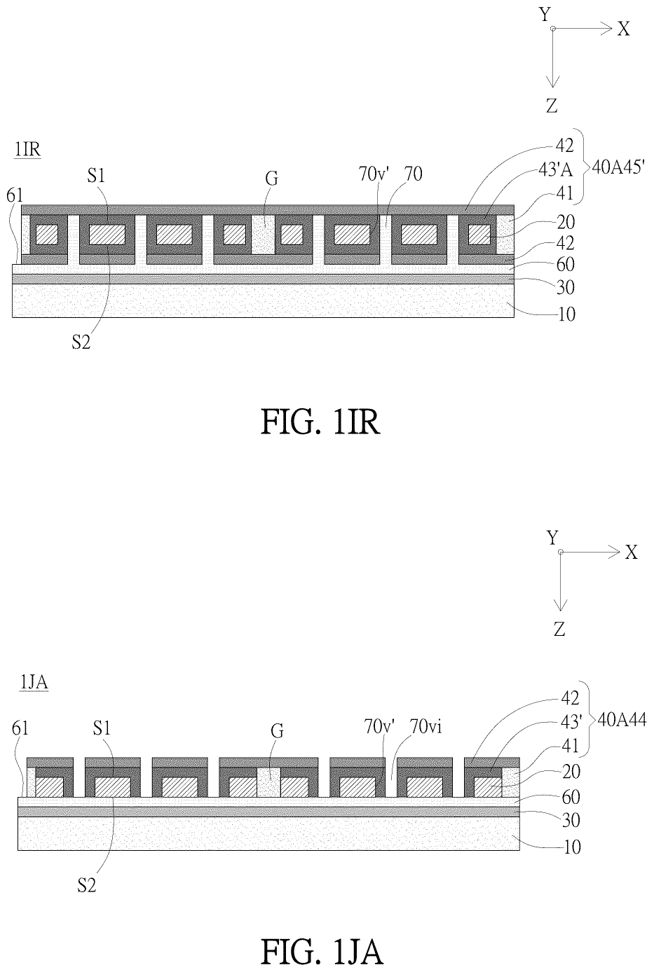

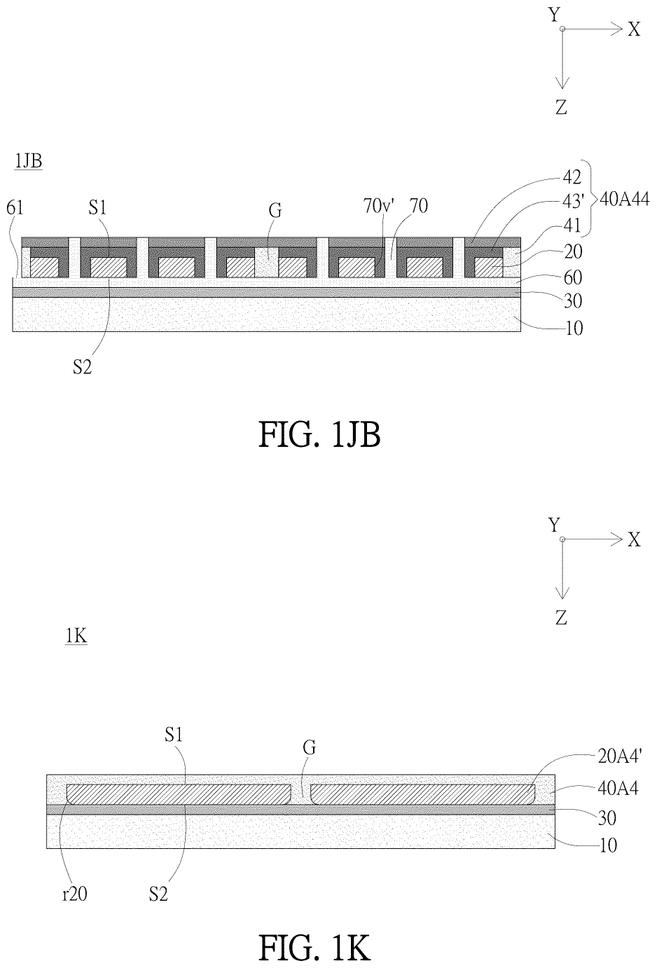

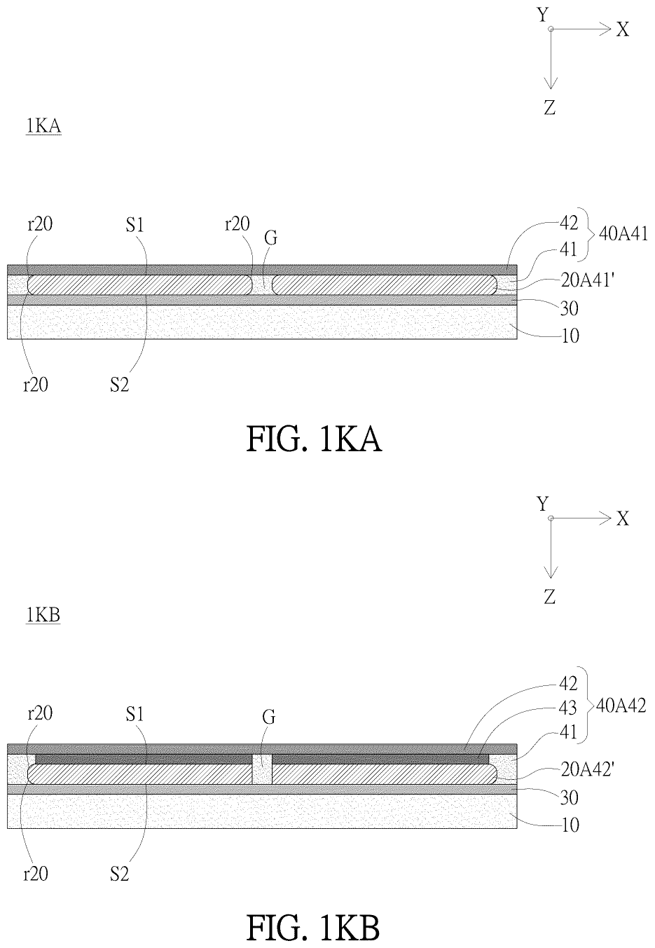

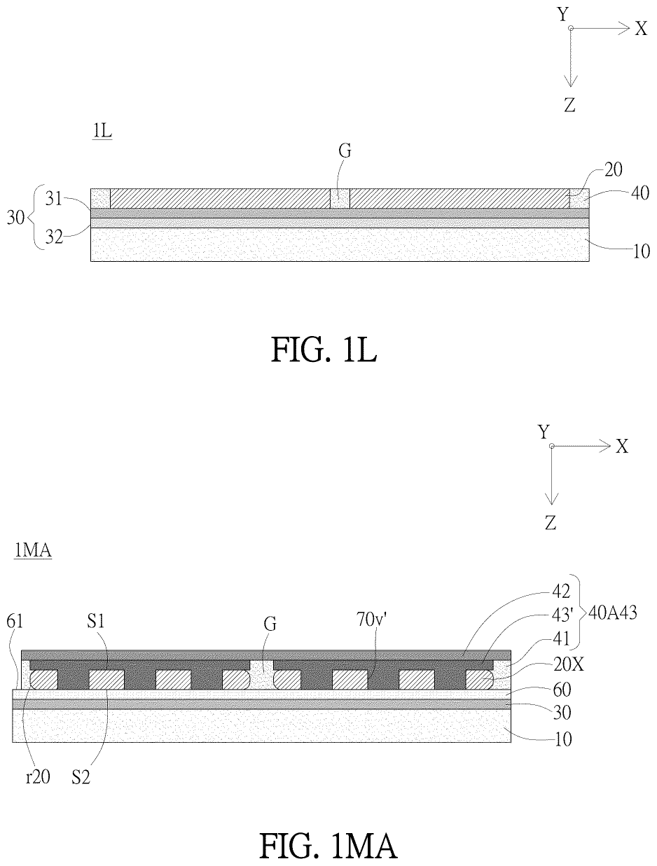

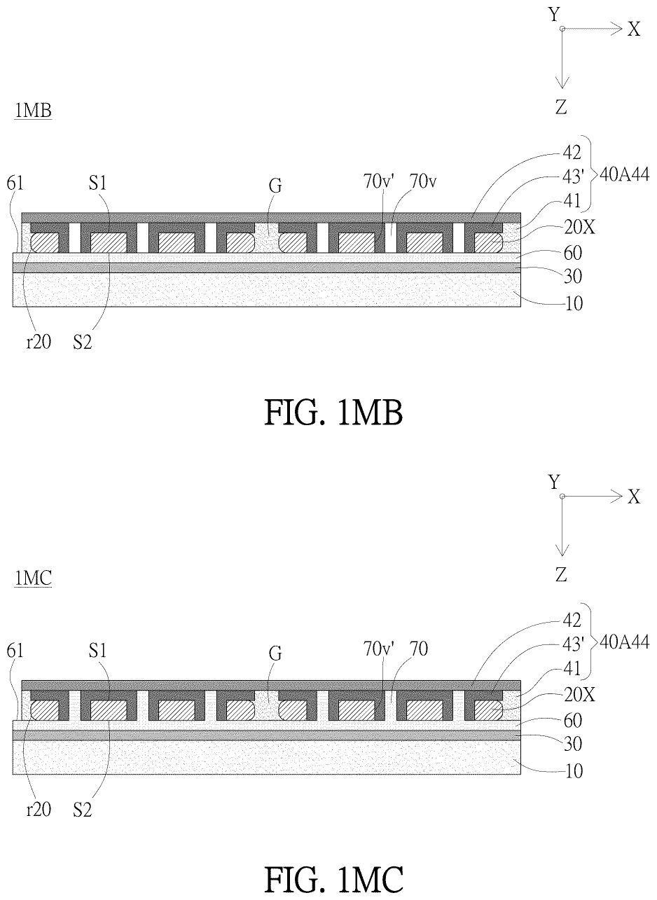

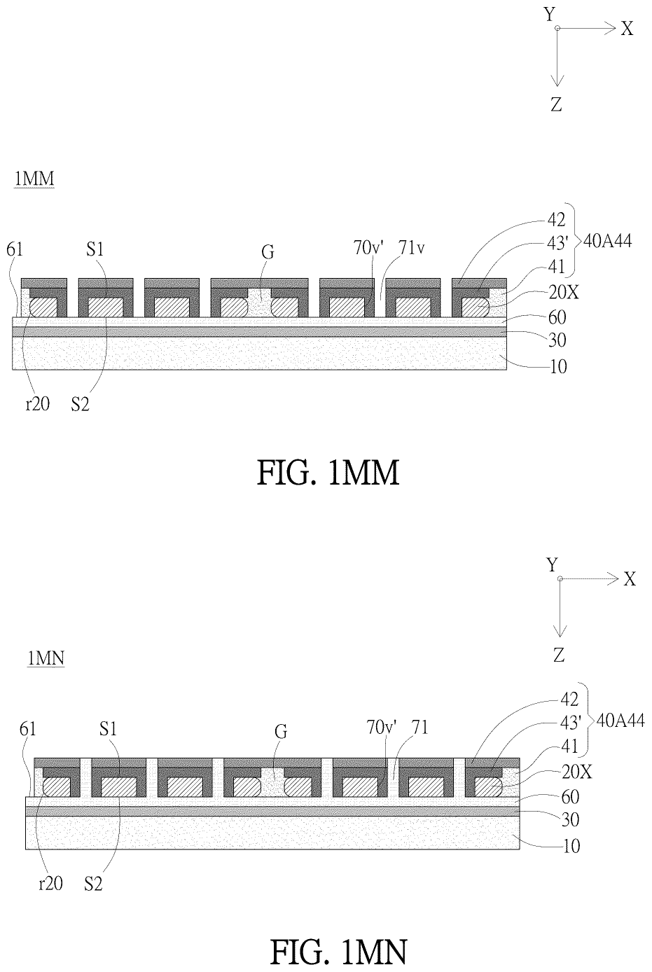

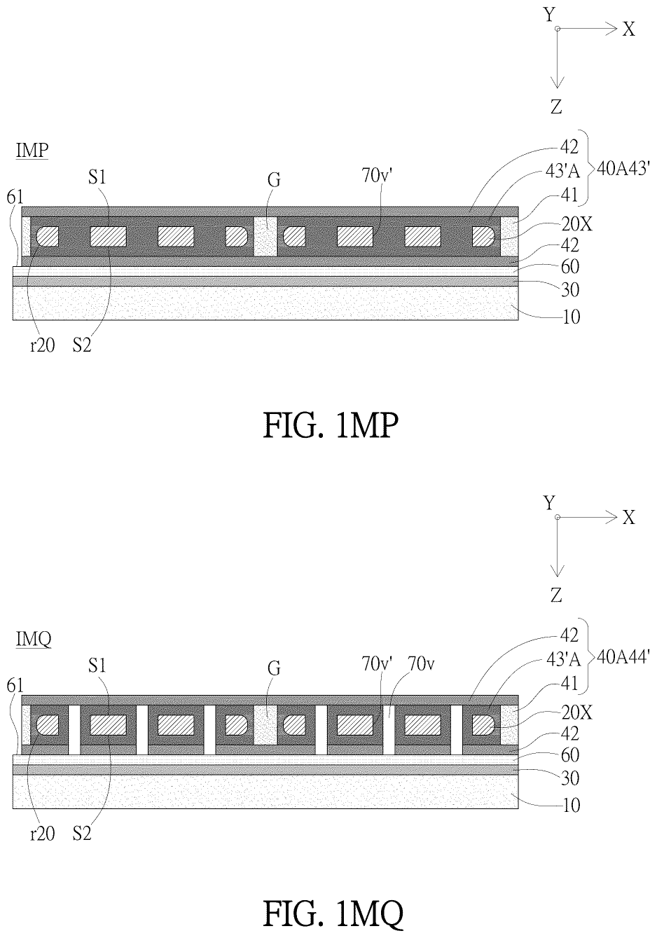

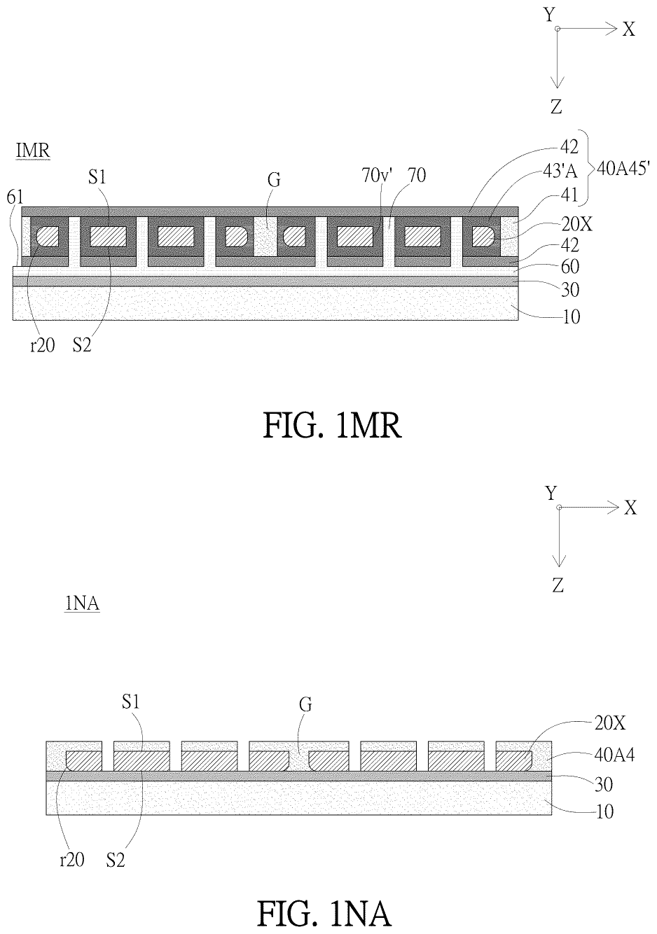

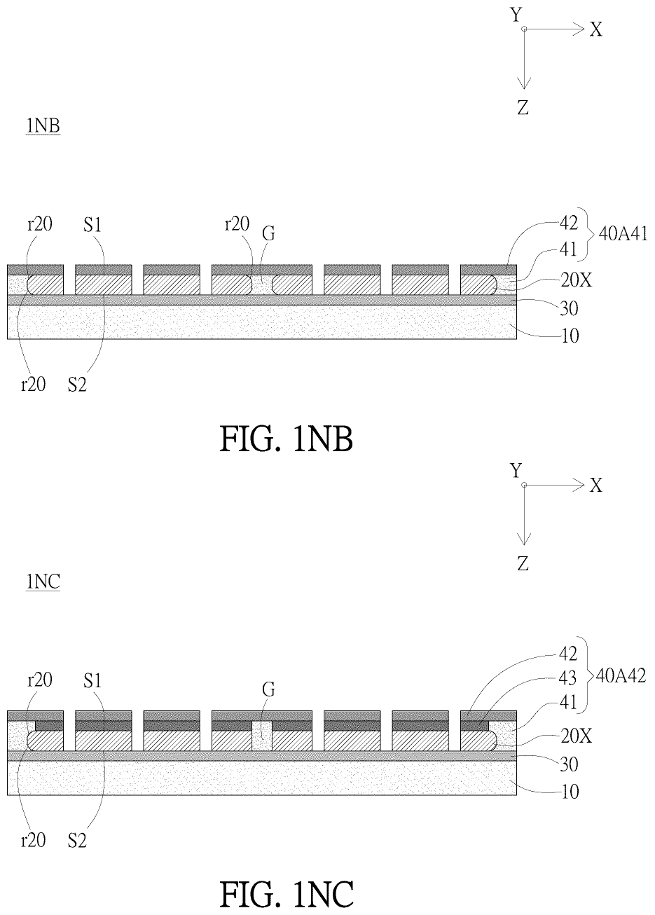

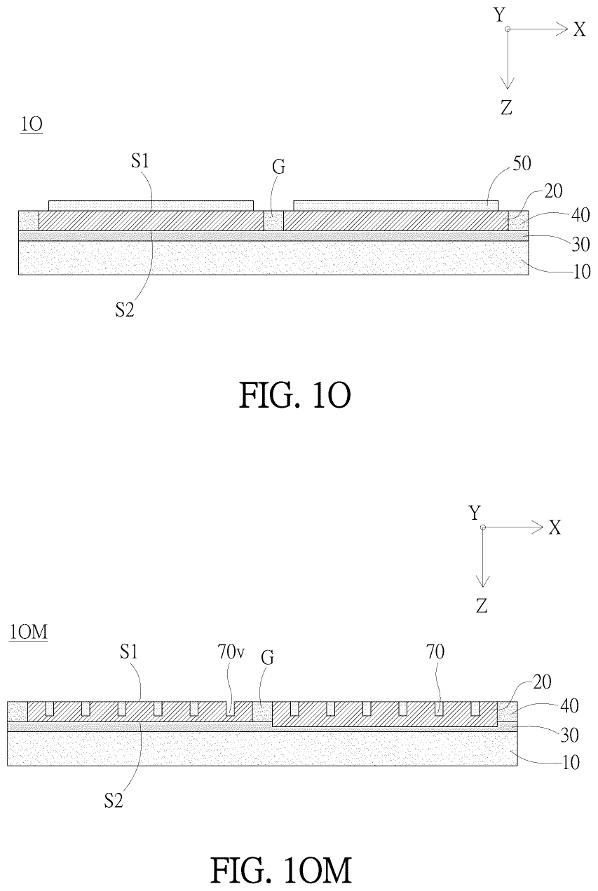

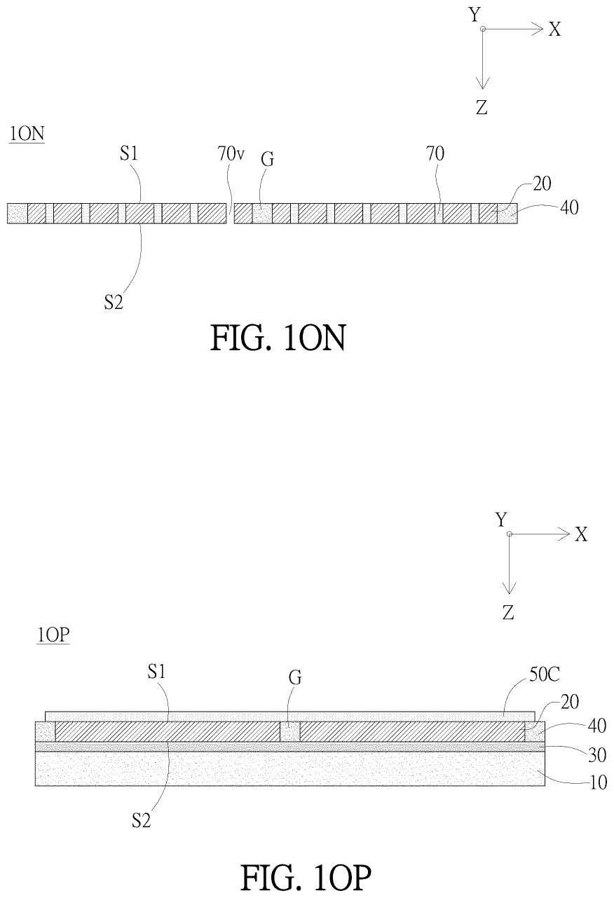

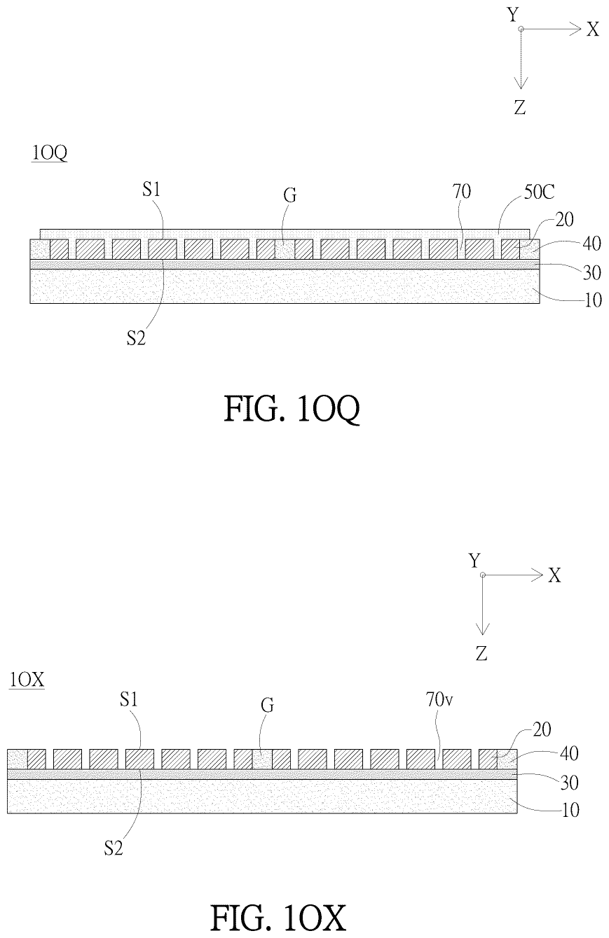

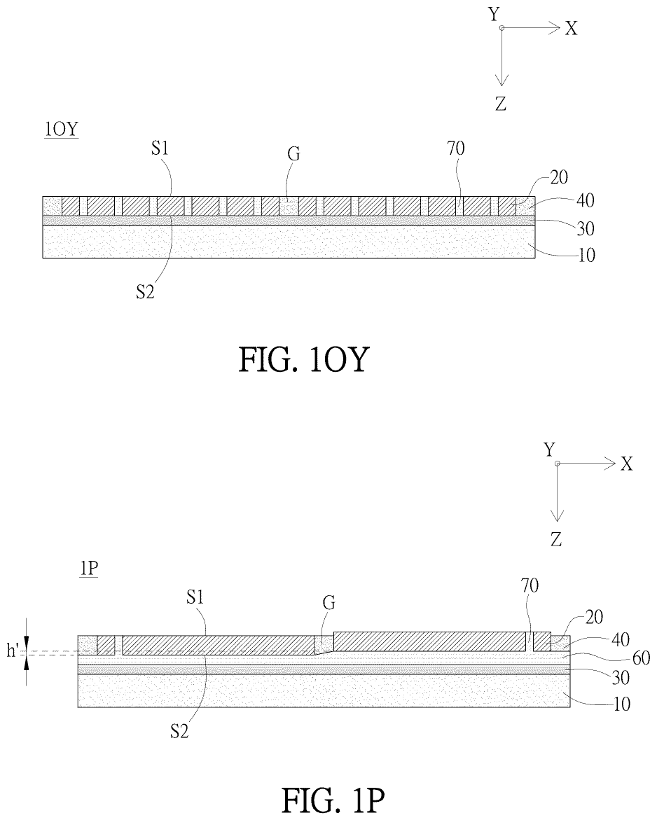

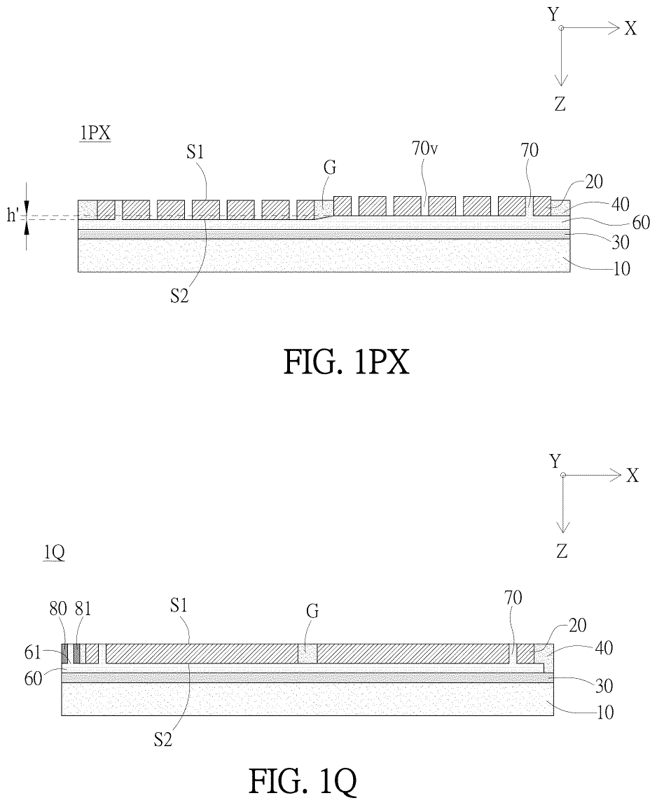

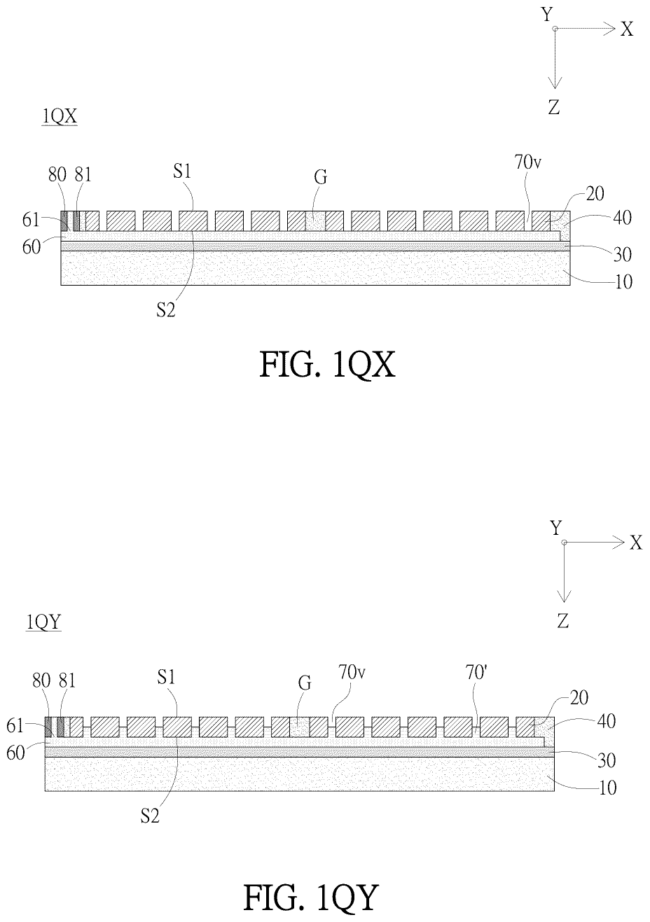

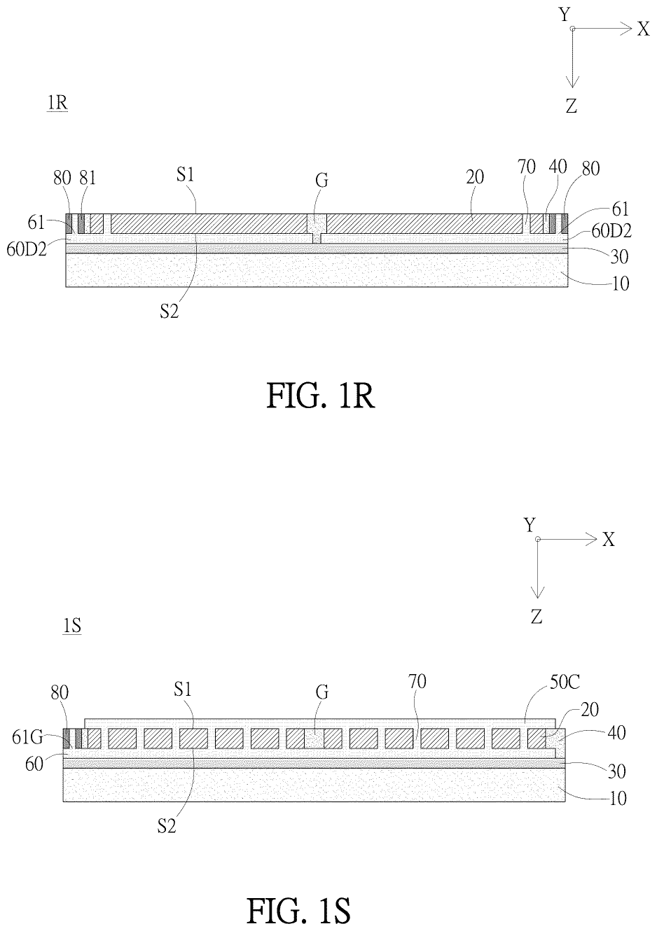

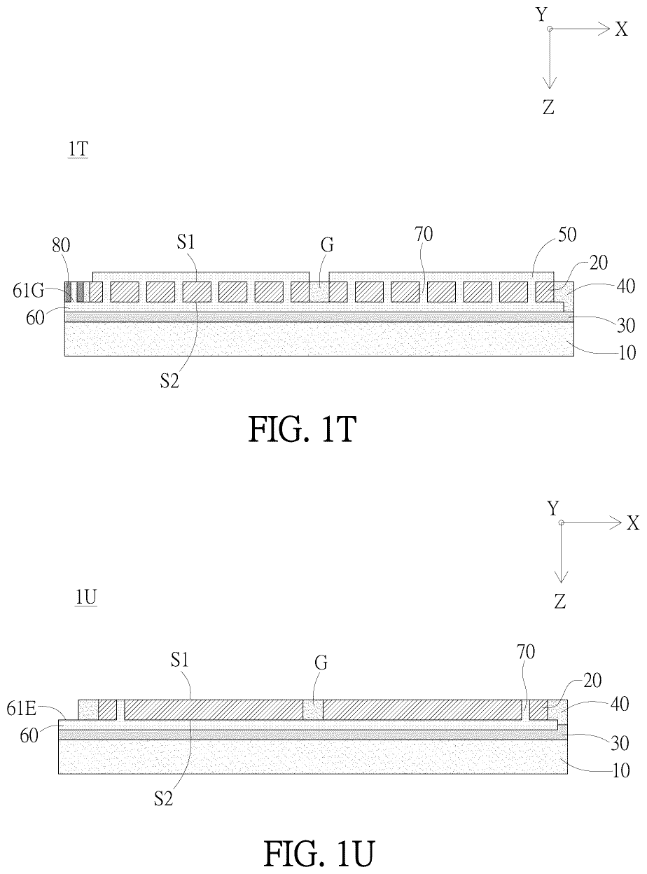

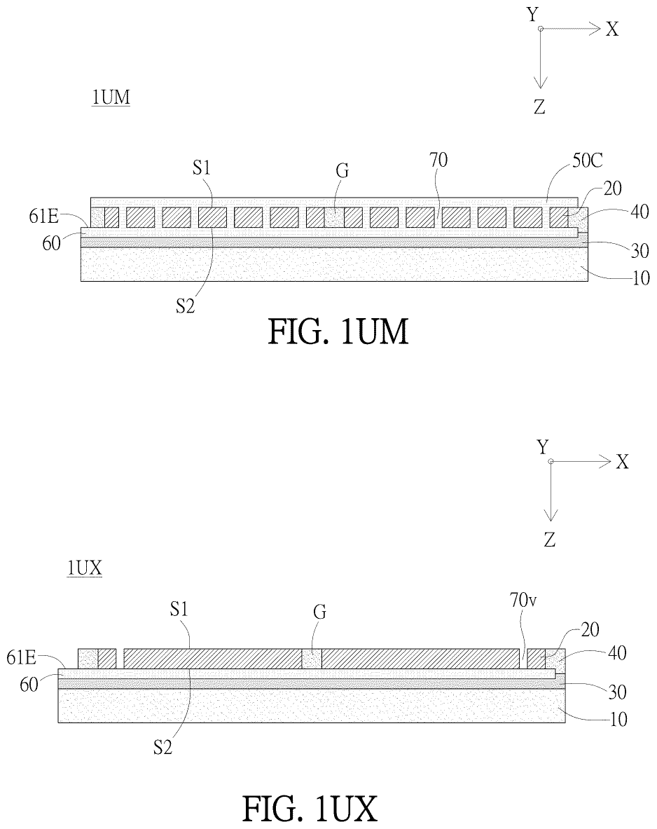

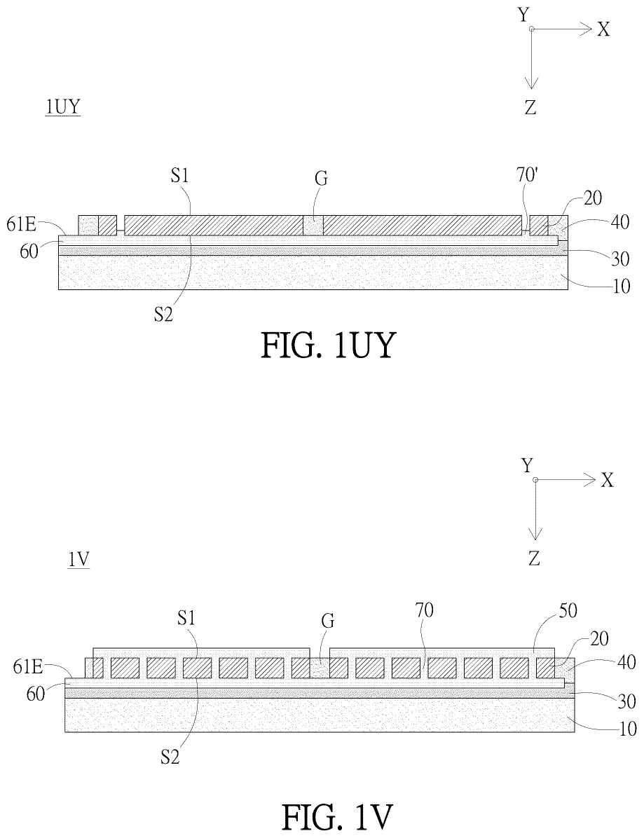

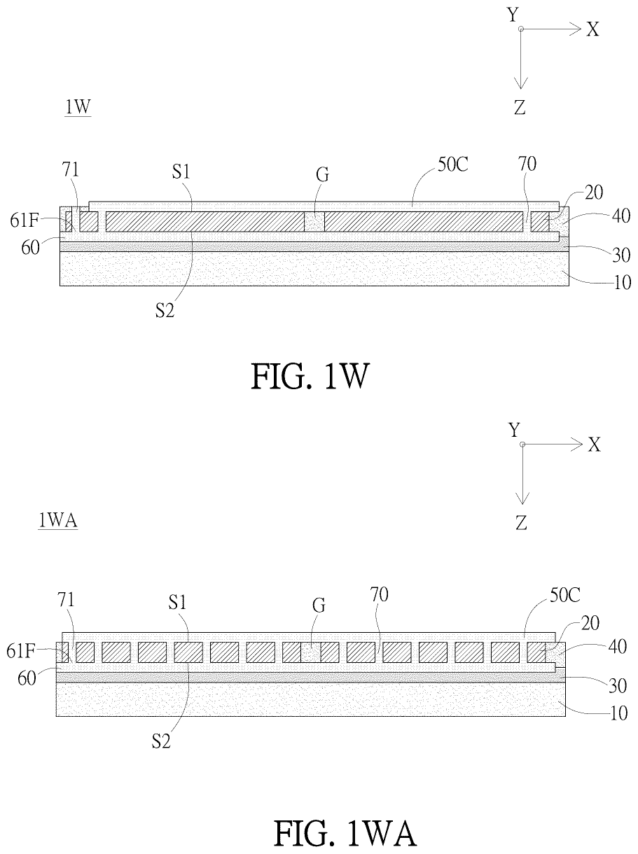

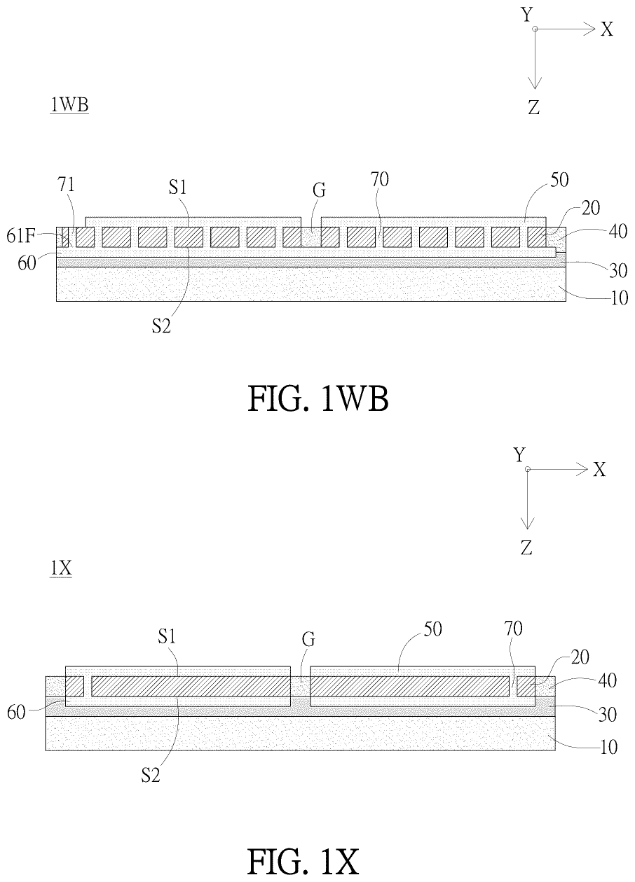

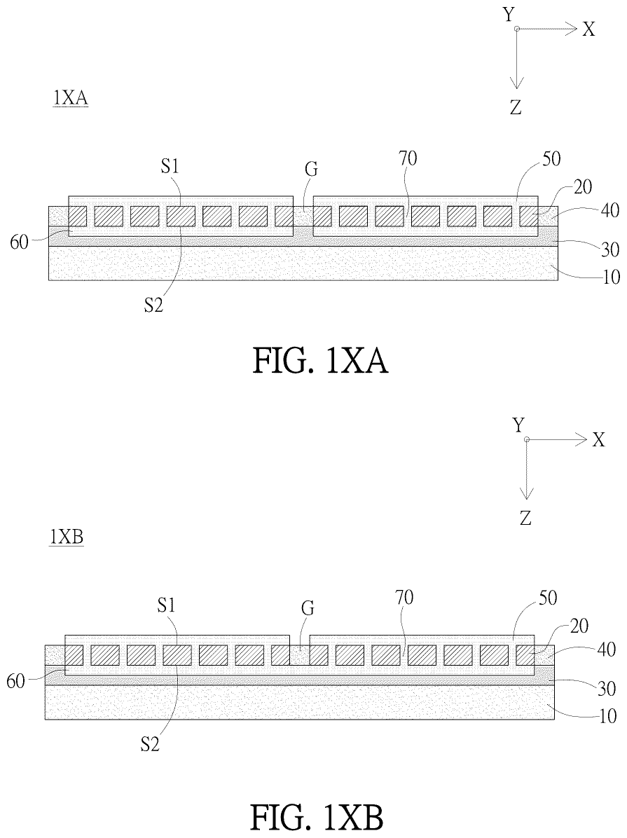

Referring to FIG. 1 and FIG. 1A, a substrate assembly 1 according to the first embodiment of the present disclosure is shown. The substrate assembly 1 includes a carrier board 10, a plurality of substrates 20, a temporary adhesive layer 30, and a functional material 40. The carrier board 10 defines a planar direction (spanned together by a horizontal direction X and a vertical direction Y, perpendicular to a vertical direction Z), and the carrier board 10 further defines one or more edges E10 according to its contour. The substrates 20 are adjacently arranged in the planar direction on the carrier board 10, for example, by tiling; each substrate 20 defines a first surface S1 and a second surface S2 opposite to each other, with the second surface S2 facing toward the carrier board 10; each substrate 20 further defines one or more corners or edges E20 according to its contour. The temporary adhesive layer 30 is arranged at least between the second surfaces S2 of the substrates 20 and the carrier board 10; the temporary adhesive layer 30 can be continuously or intermittently arranged either along the carrier board 10, here are some examples: as shown in FIG. 1, or along the second surfaces S2 of the substrates 20, as shown in FIG. 1A. The functional material 40 is at least arranged in a gap G formed between adjacent two of the substrates 20 as a gap filler, or can be further arranged around an exterior edge one or ones of the substrates 20. The planar dimensions of both the carrier board 10 and substrates 20 of the present disclosure can vary according to process requirements, and the planar dimensions of adjacent two of the substrates 20 may also be different; but in summary, the carrier board 10 has a planar area not smaller than the sum of planar areas of all substrates 20, or alternatively, the carrier board 10 defines a planar area A10 not less than twice of a planar area A20 of the smallest one of the substrate 20, wherein the carrier board 10 can accommodate a plurality of (more than two) (the smallest one of) substrates 20 on it; in the vertical direction Z perpendicular to the planar direction, a height difference h is defined between the first surfaces S1 of adjacent two of the substrates 20, this height difference h does not exceed 50 μm, this height difference h can further not exceed 10 μm, this height difference h can further not exceed 5 μm. FIG. 1 only illustrates the height difference h of the first surface S1; similarly, the same applies to the second surfaces S2 of adjacent two of the substrates 20. Please refer to FIG. 1AX, a height difference h is defined between the second surfaces S2 of adjacent two of the substrates 20, this height difference h does not exceed 50 μm, this height difference h can further not exceed 10 μm, this height difference h can further not exceed 5 μm. Furthermore, it can also be interpreted that the height difference h of the first surfaces S1 and/or second surfaces S2 of adjacent two of the substrates 20 does not exceed 1/10 of a thickness of adjacent two of the substrates 20. In principle, the height difference h, defined by the adjacent two of the substrates 20, should be as close to zero as possible to improve the flatness of a virtual plane collectively defined by the first surfaces S1 or second surfaces S2 of adjacent two of the substrates 20, so as to reduce the risk of product quality and yield issues caused by excessive height differences during subsequent circuit and patterning processes on these substrates. To reduce this height difference, the first surface S1 or second surface S2 of the substrates 20 can be planarized through a grinding process; for example, the first surfaces S1 of the substrates 20 collectively define a polished surface formed by simultaneous polishing or grinding; wherein the second surfaces S2 of the substrates 20 collectively define a polished surface formed by simultaneous polishing or grinding. That is, the first surface S1 or the second surface S2 can refer to either an unground surface of substrate 20 or a surface-treated surface. To be noted, the height difference h will not be emphasized in the illustrations after FIG. 1. In one embodiment, the edge(s) E20 of one of the substrate 20 approaches (aligns as closely as possible with) the edge(s) E10 of the carrier board 10. In one embodiment, the edge(s) E20 of the substrate 20 approaches (align as much as possible with) the edge(s) E10 of the carrier board 10, to maximize the area utilization. In some embodiments, each substrate 20 defines a flatness of not more than 10 μm on the first surface S1 or the second surface S2, and this flatness can be further defined as not more than 3 μm. The term flatness is the degree of deviation of an entire object surface relative to an ideal plane, with the measurement range covering the entire surface, used to evaluate whether the entire surface is flat.

In some embodiments, the carrier board 10 has the following characteristics. For example, the carrier board 10 includes Si, silica (silicon dioxide, SiO₂) (i.e., fused silica), glass, quartz, ceramics, glass ceramics, sapphire (Al₂O₃), compound semiconductor material, or polyimide, or any combination including one or more of the aforementioned materials. The carrier substrate 10 can be a single-layer substrate, composite substrate, or multi-layer substrate. Furthermore, the carrier board 10 is a glass substrate or a glass-ceramic substrate. In some cases, the carrier board 10 defines a coefficient of thermal expansion not greater than 15 ppm/K within a temperature range of 25° C. to 400° C. In some cases, using a rectangular carrier board 10 as an example, its planar area A10 in the planar direction is not less than 90000 mm², for example, 300*300 mm², the planar area A10 of the carrier board 10 in the planar direction is not less than 170000 mm², such as 370*470 mm², or further not less than 250000 mm², such as 500*500 mm². In some cases, the carrier board 10 defines a thickness not greater than 1 mm; this thickness can be further defined as not greater than 0.7 mm.

In some embodiments, one or ones of the substrates 20 may have the following characteristics. For example, the substrate 20 includes Si, silica (SiO₂, silicon dioxide) (i.e., fused silica), glass, silicon carbide, ceramics, glass ceramics, compound semiconductor material, or polyimide, or any combination of one or more of the aforementioned materials. In some embodiments, the substrate(s) 20 can be either a single-layer substrate, composite substrate, or a multi-layer substrate, and in some embodiments, the substrate(s) 20 can also contain or further contain organic materials. Each of the substrates 20 defines a thermal conductivity not less than 1.0 W/mK; the thermal conductivity can be further defined as not less than 2.0 W/mK. In some embodiments, each of the substrates 20 defines an elastic modulus not less than 50 GPa (Gigapascal), to further reduce the risk of warpage; the elastic modulus can be further defined as not less than 80 GPa (Gigapascal). In some embodiments, each of the substrates 20 defines a coefficient of thermal expansion not greater than 15 ppm/K within a temperature range of 25° C. to 400° C. ; the thermal expansion coefficient can be further defined as not greater than 12 ppm/K. Referring to FIG. 1C, taking the substrate(s) 20A2 as an example of a multi-layer substrate with a base material 21′, such as glass material, glass ceramic material, or ceramic material, bonded to a polyimide material, there is a difference in coefficient of thermal expansion between the polyimide material 22′ and the glass material/glass ceramic material/ceramic material 21′, which is not greater than 5 ppm/K in a temperature range of 25°C.˜400° C.; or further, not greater than 8 ppm/K or 5 ppm/K in the temperature range, to further reduce the risk of warpage. Additionally, in some embodiments, the substrate(s) 20 further defines a bending strength of not less than 150 MPa (Megapascal). In some embodiments, the substrate(s) 20 further defines a dissipation factor Df (Loss Tangent) of not greater than 0.006 at a test frequency of 10 GHz (Gigahertz). As shown in FIG. 1D, based on FIG. 1C, the carrier 10A3 can also be a multi-layer substrate with a base layer 11, such as glass material, glass ceramic material, or ceramic material, bonded to a polyimide material 12, with a difference in coefficient of thermal expansion between the polyimide material 12 and the glass material/glass ceramic material/ceramic material not greater than 5 ppm/K in a temperature range of 25° C.˜400° C.

In some embodiments, the temporary adhesive layer 30 defines a maximum thickness that is not less than the height difference h between the second surfaces S2 of adjacent two of the substrates 20. In some embodiments, the maximum thickness of the temporary adhesive layer 30 is not less than the flatness of the second surface S2 of one of the adjacent substrates 20. In some embodiments, the temporary adhesive layer 30 itself has the following characteristics. For example, the temporary adhesive layer 30 is functioned of debonding the substrate(s) 20 and the carrier board 10 from each other, such as mechanical debonding or chemical debonding. The temporary adhesive layer 30 defines a debonding temperature not less than 200° C., or defines a debonding wavelength band that absorbs a predetermined wavelength band, such as ultraviolet (UV) or green light, but not limited thereto. In some embodiments, as shown in FIG. 1L, the temporary adhesive layer 30 may include an adhesive layer 31 and a debonding layer 32, wherein the debonding layer 32 defines debonding conditions as aforementioned.

In some embodiments, the functional material 40 can, in principle, be arranged between adjacent substrates 20, and can also be further arranged on one of the surfaces of these substrates 20, especially on the outward-facing surface (including side surfaces) of these substrates 20. The functional material 40 can be configured with the same or different materials according to position, and its ultimate effect may also be different; for example, the functional material arranged between adjacent substrates 20 can be characterized as insulating or bonding, the functional material arranged on the outside of the substrate 20 can be characterized as insulating or protective, and the functional material arranged on one of the surfaces of these substrates 20 can be characterized as protective or planarizing. The above functions are only illustrative and not limiting. The functional material 40 includes organic materials and/or inorganic materials. For example, the organic materials may include epoxy resin or polyimide; the inorganic materials may include silica (SiO₂, silicon dioxide), glass, ceramics, but are not limited to these; for example, the functional material 40 includes glass frit, glass powder, glass paste, or a combination of one or more of the aforementioned materials. The functional material 40 is disposed on the substrates 20, including but not limited to, parts of the first and second surfaces that may appear in the form of build-up layers, for example, Ajinomoto Build-Up Film (ABF), such as ABF. Furthermore, the addition of inorganic materials can further enhance the relevant characteristics of the functional material 40, such as reducing CTE, increasing strength and moisture resistance. An elastic modulus of the functional material 40 is less than an elastic modulus of the adjacent substrate 20, or less than an elastic modulus of each substrate 20, to further reduce the risk of warpage.

As shown in FIG. 1E, the difference from FIG. 1AX is that in the substrate structure 1A4, the functional material 40A4 covers the surfaces of these substrates 20 facing outward, such as the first surface S1 and side surfaces, and the functional material 40A4 is formed from the same material. As shown in FIG. 1FA, the difference from FIG. 1E is that the functional material 40A41 in the substrate structure 1FA includes a plurality of materials, for example, a first functional material 41 arranged between adjacent substrates 20 and extending to the side surfaces of these substrates 20; a second functional material 42 arranged on the first surface S1 of these substrates 20, and extending to a surface of the first functional material 41 adjacent to the first surface S1. As shown in FIG. 1FB, the difference from FIG. 1FA is that the functional material 40A42 in the substrate structure 1FB includes a plurality of materials, such as a first functional material 41 arranged between adjacent substrates 20 and extending to the side surfaces of these substrates 20; a third functional material 43 arranged on the first surface S1 of these substrates 20; a second functional material 42 arranged on the outward-facing surface of these third functional materials 43, and extending to a surface of the first functional material 41 adjacent to the first surface S1; in this embodiment, the third functional material 43 can also partially or completely extend to a surface of the first functional material 41 adjacent to the first surface S1, which is not limited herein. As shown in FIG. 1IA, the functional material 40A43 in the substrate structure 1IA still includes a plurality of materials, and the difference from FIG. 1FB is that the substrate structure 1IA includes a second conductive layer structure 60, the second conductive layer structure 60 defines one or more feed areas 61 for external electrical connection, and these substrates 20 have a plurality of through holes 70v′, and the functional material 40A43 (for example but not limited to the third functional material 43′) fills these through holes 70v′. As shown in FIG. 1IB, the functional material 40A44 in the substrate structure 1IB still includes a plurality of materials, and the difference from FIG. 1IA is that these functional materials 40A44 (for example but not limited to the third functional material 43′) filling these through holes 70v′ further have inner holes 70vb; herein, the inner holes 70vb can be coaxially arranged with the through holes 70v′, but not limited thereto; herein, the wall of the inner holes 70vb is, preferably, defined by the functional material 40A44, but not limited thereto; in this embodiment, the through holes 70v do not penetrate the second functional material 42. As shown in FIG. 1IC, the functional material 40A45 in the substrate structure 1IAC still includes a plurality of materials, and the difference from FIG. 1IB is that conductive material fills these inner holes 70vb to form a plurality of conductive vias 70. Please refer to FIG. 1JA, the difference from FIG. 1IB is that: in the substrate structure 1JA, a plurality of inner holes 71vi penetrate the second functional material 42; these inner holes 71vi are similarly formed by further opening in the functional material 40A44 (for example but not limited to the third functional material 43′) that fills these through holes 70v′. Please refer to FIG. 1JB, the difference from FIG. 1IC is that: in the substrate structure 1JA, the conductive material fills these inner holes 71vi to form a plurality of conductive vias 71. It can be understood that although the substrate structure does not contain many components, there can be many different arrangements and combinations. It is worth noting that those through holes 70v′, inner holes 71vi can also, as shown in FIG. 1OM, be holes connecting to only one surface, for example, the first surface S1 of the substrate 20; in this case, they can also be referred to as holes. Compared to the substrate structures 1IA, 1IB, and 1IC in FIG. 1IA to 1IC, in the substrate structures 1IP, 1IQ, and 1IR of FIG. 1IP to 1IR, the third functional material 43A′ more completely encapsulates the substrates 20.

As shown in FIG. 1G, the functional material 40A4A in the substrate structure 1G encapsulates all surfaces of the substrates 20, including the first and second surfaces S1 and S2 and opposite side surfaces; the functional material 40A4A1 may be formed from the same material. As shown in FIG. 1GA, the functional material 40A4A1 in the substrate structure 1GA includes multiple materials; for example, a first functional material 41 is disposed between two adjacent substrates 20 and extends to the side surfaces of the substrates 20; a second functional material 42 is disposed on the first and second surfaces S1 and S2 of the substrates 20, and extends respectively to two opposite surfaces of the first functional material 41 adjacent to the first and second surfaces S1 and S2. As shown in FIG. 1GB, the functional material 40A4A2 in the substrate structure 1GB includes multiple materials; for example, a first functional material 41 is disposed between two adjacent substrates 20 and extends to the side surfaces of the substrates 20; third functional materials 43 are disposed on the first and second surfaces S1 and S2 of the substrates 20; two second functional materials 42 are respectively arranged on the first and second surfaces S1 and S2 of the substrates 20, wherein the second functional materials 42 are disposed on the outward-facing surfaces of the third functional materials 43 and extend to two opposite surfaces of the first functional material 41 adjacent to the first and second surfaces S1 and S2.

There are more implementations of functional materials, but not limited to these; for example, as shown in FIG. 1GM, the functional material 40A4A1′ in substrate structure 1GM includes a plurality of materials, such as a first functional material 41A′ covering all surfaces of the substrates 20, including the first and second surfaces S1, S2, and the two opposite side surfaces; the second functional material corresponds to the first and second surfaces S1, S2 of these substrates 20, and extends to the two opposite surfaces of the first functional material 41A′. For example, as shown in FIG. 1GN, the functional material 40A4A2′ in substrate structure 1GN includes a plurality of materials, such as a third functional material 43A′ covering all surfaces of these substrates 20, including the first and second surfaces S1, S2 and the two opposite side surfaces; the first functional material 41 correspondingly arranged between two adjacent substrates 20, in this embodiment, the first functional material 41 is located between two third functional materials 43A′; the second functional material corresponds to the first and second surfaces S1, S2 of these substrates 20, and extends to the two opposite surfaces of the third functional material 43A′.

Furthermore, these substrates 20 can be designed with chamfered structures at one or more corners or edges; taking substrate structures 1K, 1KA, and 1KB shown in FIGS. 1K 1KA, and 1KB as examples; the chamfers r20 are located on the side of substrate 20A4′ facing the carrier board 10, on both side edges of substrate 20A41′, and on the outward-facing side edge of substrate 20A42′; however, the configuration relationships of the aforementioned chamfered structures on the substrates are not limited to these. It can be understood that the implementation of the chamfered structures described in this document can also be applied to the substrates in all embodiments herein (including blank boards and non-blank boards).

Referring to FIG. 1H˜FIG. 1HB, FIG. 1HC˜FIG. 1HD,the difference from FIG. 1G˜FIG. 1GB is that the substrates 20X all have chamfers r20. In this example, all four side edges have chamfers, but this is not limited to this configuration. Thereby increasing the adhesion strength and mechanical properties between the functional material and the substrate.

Referring to FIG. 1MA˜FIG. 1MC, FIG. 1NA˜FIG. 1NB˜FIG. 1NC, FIG. 1MM˜FIG. 1MN, and the difference from FIG. 1MA˜FIG. 1MC, FIG. 1K, FIG. 1KA˜FIG. 1KB, FIG. 1JA˜FIG. 1JB is that the substrates 20X all have chamfers r20. In this example, all four side edges have chamfers, but this is not limited to this configuration. Thereby increasing the adhesion strength and mechanical properties between the functional material and the substrate.

In some embodiments, the substrates 20 and the functional material 40 together constitute a composite substrate. For example, the elastic modulus or the CTE of this composite substrate is similar to the elastic modulus or the CTE of the carrier board 10, to further reduce the risk of warpage.

As shown in FIG. 1O and FIG. 1OP, the substrate assemblies 1O, 1OP further includes a first electrical layer structure 50, 50C, which is arranged at least on the first surface S1 of each of the substrates 20. The difference between the first electrical layer structure 50, 50C in FIG. 1O and FIG. 1OP lies in that the first electrical layer structure 50 in FIG. 1O is only arranged on the substrates 20, while the first electrical layer structure 50C in FIG. 1OP can further extend upon the functional material 40 between adjacent two of the substrates 20. In some embodiments, the first electrical layer structure 50C can further extend upon the functional material 40 around the exterior edge of the substrate 20. In some embodiments, the first electrical layer structure 50, 50C can be either a conductive layer which is non-patterned (i.e., a complete conductive layer covering the entire surface) or a circuit layer which is patterned. In some embodiments, the substrate 20 can be either an undefined substrate or a defined substrate, where the meaning of “defined” includes at least: whether through holes exist, whether conductive vias exist, and whether conductive layers exist-a substrate where none of these three conditions exist is considered undefined. For example, the first electrical layer structure 50 can be an electrical layer structure inherent to the substrate 20 (i.e., the substrate 20 here is a defined substrate) before the substrate 20 is arranged on the carrier board 10, or as in the case of the first electrical layer structure 50C, which is an electrical layer structure arranged thereon after the substrate 20 (i.e., the substrate 20 is an undefined substrate) is first arranged on the carrier board 10, and then the first electrical layer structure 50C is arranged on it, in which case the first electrical layer structure 50C is not an electrical layer structure that comes with the substrate 20. When the first electrical layer structures 50, 50C are non-patterned conductive layers, they can be single electrical layers; when the first electrical layer structures 50, 50C are patterned circuit layers, they can be multi-layer electrical redistribution layers (RDL). As shown in FIG. 1OQ and 1OX, in a substrate assembly 1OX, each of the substrates 20 includes one or more through holes 70v, wherein the through holes 70v communicate with at least one of the first surface S1 and the second surface S2 of a corresponding one of the substrate 20, or further communicate with both aforementioned surfaces S1 and S2; in a substrate assembly 1OQ, each of the substrates 20 includes one or more conductive vias 70, wherein the conductive vias 70 are at least electrically connected to the first electrical layer structure 50. The conductive vias 70 can be pre-formed in each substrate 20, or can be formed by drilling and depositing conductive material after the substrates 20 are arranged on the carrier board 10; or can be formed by depositing conductive material into through holes 70v that are pre-formed in each substrate 20 after the substrates are arranged on the carrier board 10. As shown in FIG. 1OY, the difference between substrate assembly 1OY and substrate assembly 1OQ is that substrate assembly 1OY lacks the first electrical layer structure 50C. As shown in FIG. 1OM and FIG. 1ON, the key point of substrate assembly 1OM is that its through holes 70v or conductive vias 70 only communicate with either the first surface S1 or the second surface S2, with this embodiment using communicate with the first surface S1 as an example; the through holes 70v or conductive vias 70 of substrate assembly 1ON simultaneously communicate with both the first surface S1 and the second surface S2. This double-sided communicate design can be completed either during the initial drilling of through holes 70v to achieve double-sided communicate design, or by polishing or grinding the unconnected side of the through holes 70v or conductive vias 70 in substrate assembly 1OM to achieve double-sided communicate design.

As shown in FIG. 1P, a substrate assembly 1P further includes a second electrical layer structure 60, which is arranged at least between the second surface S2 of each of the substrates 20 and the temporary adhesive layer 30; the second electrical layer structure 60, like the first electrical layer structure 50, can extend between the functional material 40 between adjacent substrates 20 and the temporary adhesive layer 30, and can further extend between the functional material 40 around the exterior edge(s) of one or ones of the substrates 20 and still sandwiched by the corresponding substrates 20 and the temporary adhesive layer 30. When the second electrically conductive layer structure 60 is disposed on at least adjacent two of the substrates 20 and the arrangement material 40 located between the adjacent two of the substrates 20, in the vertical direction Z perpendicular to the planar direction, a height difference h′, which is not greater than 5um, is defined between the second surfaces S2 of the adjacent two of the substrates 20, as shown in FIG. 1P. Similarly, the second electrical layer structure 60 can be either a conductive layer which is non-patterned or a circuit layer which is patterned; the second electrical layer structure 60 can also be either a single circuit layer or a multi-layered redistribution circuit layer. Furthermore, the second electrical layer structure 60 can be an electrical layer structure to each of the substrate 20 before attaching onto the temporary adhesive layer 30. As shown in FIG. 1P, in the substrate assembly 1P, each of the substrates 20 includes one or more conductive vias 70, wherein the conductive vias 70 are at least electrically connected to the second electrical layer structure 60. It is worth noting that the conductive vias 70 provide electrical connectivity possibilities between the first surface S1 and the second surface S2 of the substrate 20, and the conductive vias 70 are typically extends along the vertical direction Z; in some embodiments, the conductive vias 70 may include a barrier layer (not illustrated), a liner layer (not illustrated), a seed layer (not illustrated), and/or filling materials, such as when using electroplating methods; the conductive vias may contain conductive materials or further contain insulating materials. As shown in FIG. 1PX, in a substrate assembly 1PX, each of the substrates 20 includes one or more through holes 70v, wherein the through holes 70v communicate with the first surface S1 and the second surface S2 of the substrate 20. The through holes 70v can be pre-formed in each substrate 20, or can be formed by drilling after the substrates 20 are arranged on the carrier board 10.

As shown in FIG. 1P, the conductive vias 70 can either be inherent conductive vias of the substrate 20 that are then combined with the carrier board 10 through the temporary adhesive layer 30, or they can be formed through subsequent processes after combining with the carrier board 10 through the temporary adhesive layer 30, such as through electroplating processes. As shown in FIG. 1Q and FIG. 1R, the substrate assemblies 1Q and 1R include a second electrical layer structure 60 that includes a feeding area 61, which is typically located at the periphery (the edge or edges) of the second electrical layer structure 60, though this is not limited to such placement; one of the functions of this feeding area 61 is to provide power feeding through various conductive via formation methods through electrically connecting the second electrical layer structure 60. In these embodiments, although the feeding area 61 is not covered by the arrangement material 40, the substrate assemblies 1Q and 1R may further include one or more feeding boards 80, which are independent substrates separate from substrate 20, adjacent to their corresponding substrates 20, and electrically connected to the second electrical layer structure 60 (specifically its feeding area 61). The difference between FIG. 1Q and FIG. 1R is that in FIG. 1R, the second electrical layer structure 60 can correspond to a plurality of substrates 20 simultaneously, while in FIG. 1R, the second electrical layer structure 60 corresponds to individual substrates 20, and the number of feeding boards 80 corresponds to the number of independent second electrical layer structures 60, thus corresponding to individual substrates 20. Specifically, these feeding boards 80 inherently have one or more conductive vias 81 that electrically connect to the second electrical layer structure 60 (its feeding area 61), and these conductive vias 81 can be formed through various methods such as chemical plating, electroplating, sintering, and so on. Referring to FIG. 1QX and 1QY, before the electroplating process, the through hole 70v in FIG. 1QX is not yet filled with any conductive material, while during the electroplating process, the feeding area 61 and the exposed portion of the second electrical layer structure 60 corresponding to the through hole 70v can serve as the two electrodes for charging and discharging in the electroplating process, gradually forming a conductive material 70′ shown in FIG. 1QY within the through hole 70v, ultimately forming the conductive via 70 shown in FIG. 1P, and these conductive vias 70 are at least electrically connected to the second electrical layer structure 60. As shown in FIG. 1S, in one or ones of the substrates 20, there are a plurality of conductive vias 70; additionally, the substrate assembly can further include one or more first electrical layer structures, where these conductive vias 70 electrically connect the first and second electrical layer structures 50 and 60; in substrate assembly 1S, a single first electrical layer structure 50C is electrically connected to the second electrical layer structure 60 through these conductive vias 70 of ones or all of the substrates 20; as shown in the substrate assembly 1T of FIG. 1T, a plurality of first electrical layer structures 50 correspond to a plurality of substrates 20 and are electrically connected to the second electrical layer structure 60 through those conductive vias 70 in those substrates 20, with each of the first electrical layer structures 50 and its corresponding substrate 20 forming independent units (when not electrically connected through other circuits).

FIG. 1U to FIG. 1V show substrate assemblies 1U˜1V similar to the previous embodiments, with the difference being that the feeding area 61E is directly represented by exposing the second electrical layer structure 60, thereby achieving the same effect as the feeding board. FIG. 1UX to FIG. 1UY show substrate assemblies 1UX˜1UY respectively, demonstrating that in the embodiment with feeding area 61E, during the electroplating process, the conductive material 70′ shown in FIG. 1UY is gradually formed within the through hole 70v shown in FIG. 1UX, ultimately forming the conductive via 70 shown in FIG. 1U.

FIG. 1W to FIG. 1WB show substrate assemblies 1W, 1WA. 1WB similar to the previous embodiments, with the difference being that the feeding area 61F is electrically connected to predetermined conductive vias 71 of the substrates 20, thereby achieving the same effect as the feeding board 80; here, the predetermined conductive vias 71 of the substrate 20 remain part of the substrate 20 rather than being an independent substrate. These predetermined conductive vias 71 serve the same function as the conductive vias 81 of the feeding board 80, and can be pre-formed through various methods such as chemical plating, electroplating, or sintering, followed by the electroplating process to form the conductive vias 70. In other words, in the substrate assembly of this invention, some of the conductive vias 70 on the substrate 20 can be used for power feeding purposes.

FIG. 1X to FIG. 1XA, in the substrate assembly 1X˜1XA, the substrates 20 inherently include first and second electrical layer structures 50, 60, and one or more conductive vias 70. Some of the conductive vias 70 can electrically connect the first electrical layer structure 50 and the second electrical layer structure 60. In FIG. XB, the substrate assembly XB has substrates 20 that inherently include the first electrical layer structure 50 and one or more conductive vias 70; the second electrical layer structure 60 is formed on the second temporary adhesive layer 30 before bonding to the temporary adhesive layer 30 (and its carrier board 10).

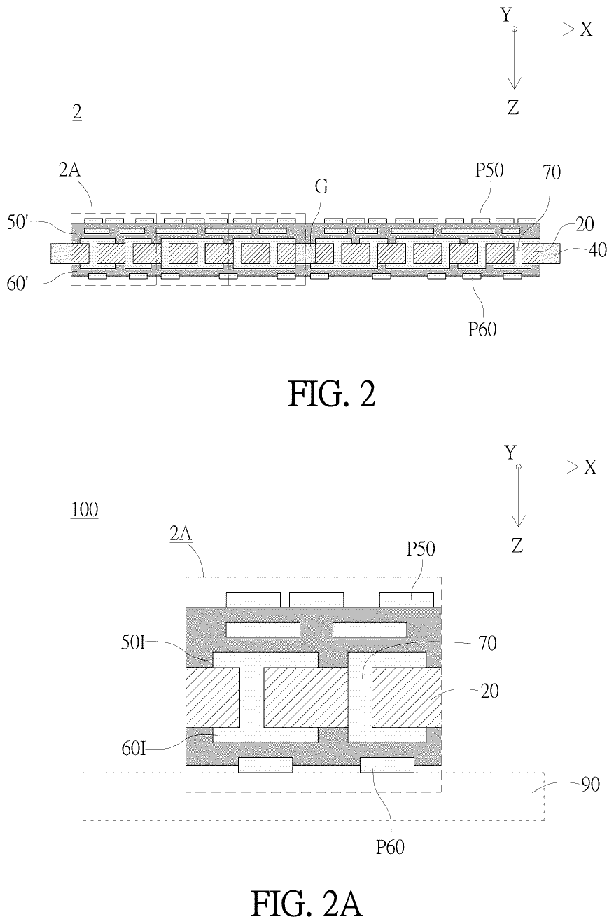

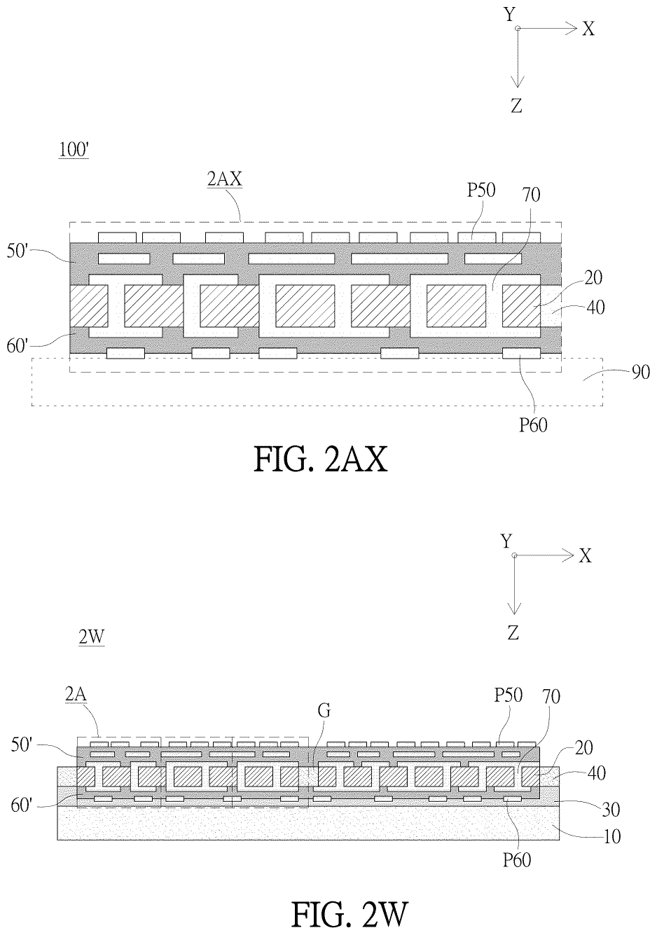

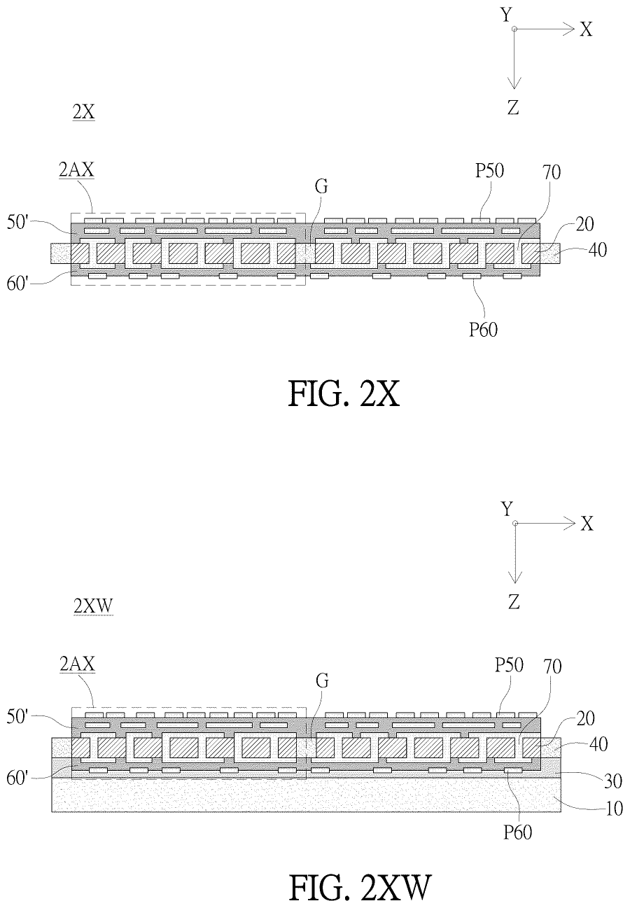

The substrate assembly of the present invention allows size-restricted substrates 20 to be arranged on the carrier board 10 to form a large-size substrate for subsequent processing, as shown in FIG. 2W and FIG. 2, providing separation means corresponding to the carrier board 10 for the separation characteristics of the temporary adhesive layer 30, such as providing light of a specific wavelength or applying heat, allowing the carrier board 10 to separate from the a plurality of completed and arranged substrates 20, at which point the a plurality of substrates 20 rely on the functional material 40 to form an integral structure. A first and second electrical layer structures 50′, 60′ can each be a redistribution structure as shown in FIG. 2 (but not limited thereto). The processing of the first electrical layer structure 50′ can be completed before the removal of the carrier board 10, while the second electrical layer structure 60′ can be completed after the removal of the carrier board 10. The first and second electrical layer structures 50′, 60′ have maximum line widths P50 and P60 respectively, where the maximum line width P50 of the first electrical layer structure 50′ is smaller than the maximum line width P60 of the second electrical layer structure 60′. In this way, circuit processing can be performed simultaneously on a plurality of substrates 20 (but not limited to this), ultimately forming a tiled substrate assembly with double-sided circuits, which effectively reduces costs; at this time, the substrate assembly 2 is removed from the temporary adhesive layer 30 and peeled from the carrier board 10 and can be further define a plurality of cutting units 2A, wherein each of the cutting units 2A is free of any gap G. It is worth noting that the size of each cutting unit is greater than or equal to the size of one of the substrates. Furthermore, as shown in FIG. 2A, this double-sided circuit tiled substrate assembly can be further cut according to requirements to produce cutting units 2A for industry use, such as in advanced packaging applications, for example, an assembly package 100 includes an electrical board 90 and a portion of the substrate assembly 2 disposed on the electrical board 90; this portion of the substrate assembly 2 includes one or ones of the cutting units 2A, thus the assembly package 100 also includes the aforementioned cutting unit 2A. In this case, the size of the substrate 20 in the substrate structure 2 is much larger than the size of the cutting unit 2A after the cutting process; the substrate 20 in the reference FIG. can be cut into 3 cutting units 2A.

Please refer to FIG. 2 and FIG. 2XW, using FIG. 2 and FIG. 2X (but not limited to these) as the basis for explanation. In this embodiment, the substrate structure 2X defines a plurality of cutting units 2AX, each cutting unit 2AX similarly does not contain gap G. Here, the substrate structure 2′includes first and second electrical layer structures 50′, 60′ as a redistribution layer structure as an example, but is not limited to this. The main difference between substrate structure 2X and substrate structure 2 is that the size of the substrate 20 in substrate structure 2X is close to the size of the cutting unit 2AX after the cutting process (i.e., similar in size), so the cutting process only separates a plurality of substrates 20 from each other without dividing a single substrate 20 into a plurality of parts. This usually occurs when the substrate 20 itself is small enough. In contrast, the size of the substrate 20 in substrate structure 2 is larger than the size of the cutting unit 2A after the cutting process, so the cutting process can divide a single substrate 20 into a plurality of parts. In this embodiment, the cutting process only separates a plurality of substrates 20 from each other, and the functional material 40 can be retained, for example, covering the side edges of each substrate 20, thereby achieving an edge protection effect. It is worth noting that substrate 20 can exist with conductive vias 70, conductive layers 50′, 60′ as in this embodiment, or it can be a blank board.

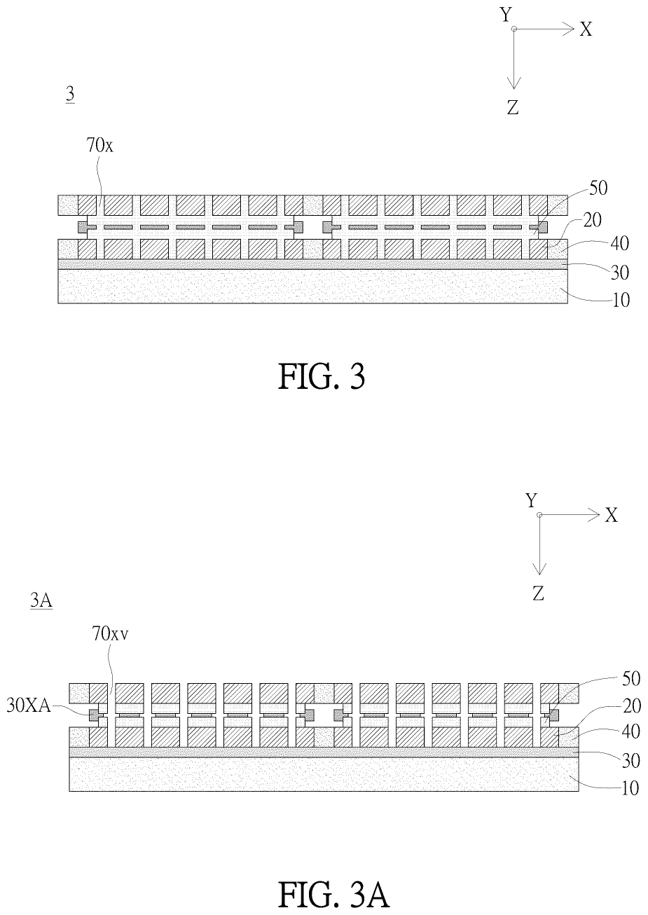

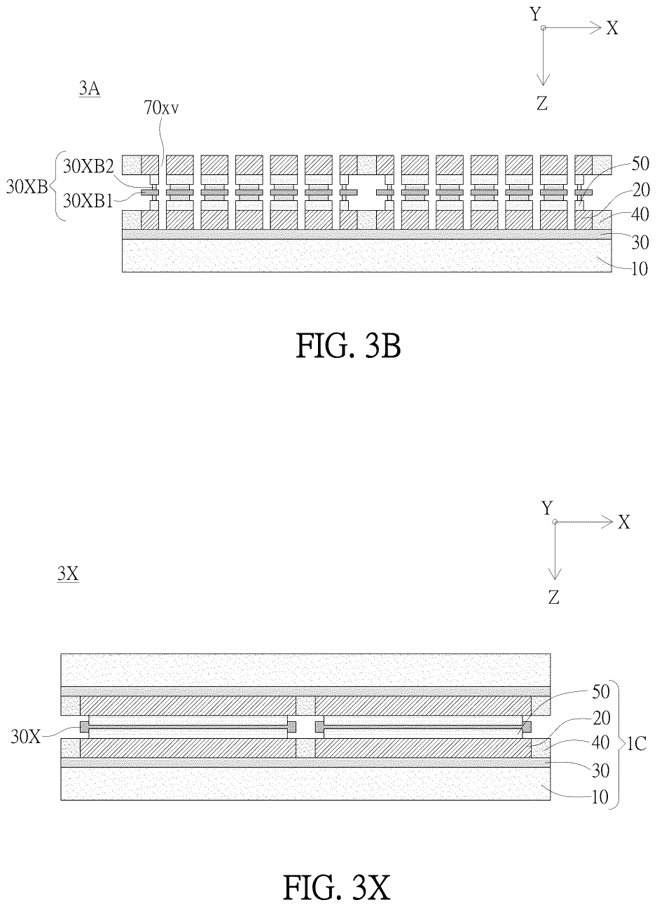

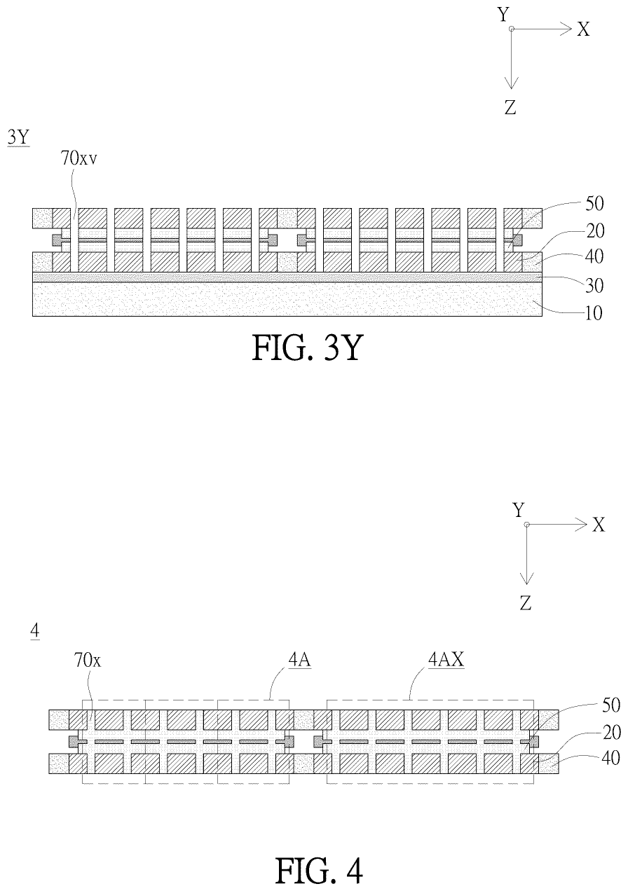

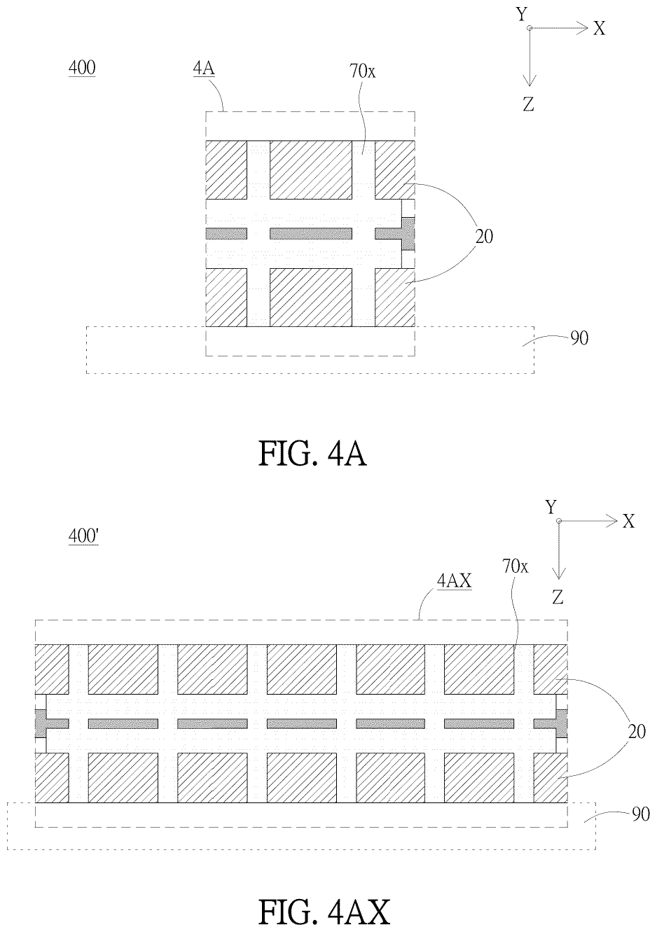

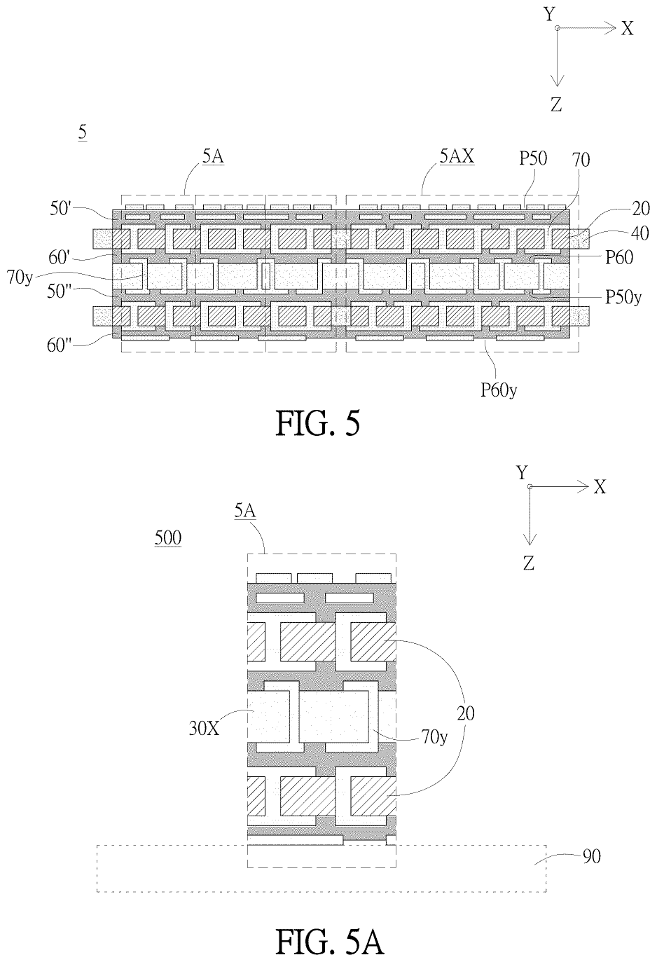

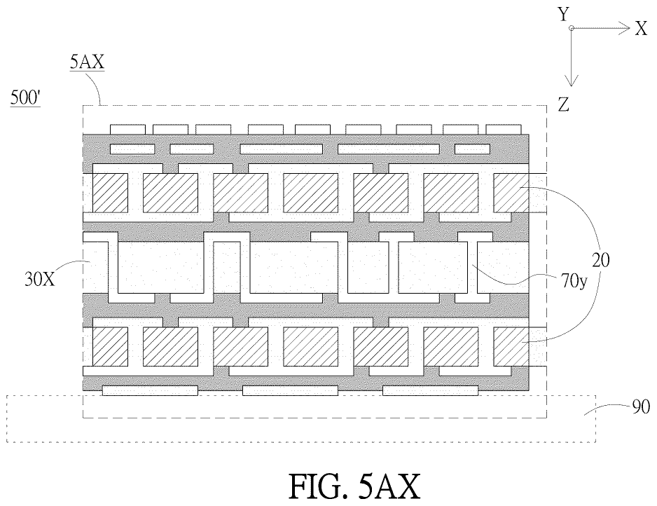

The substrate assembly in the present invention can be further applied as follows: FIGS. 3 to 5A respectively show different embodiments of the substrate assembly 2 (FIGS. 3, 3X, 3Y), and different types of cutting units (FIGS. 4, 4A, 5, 5A), a portion of the substrate assembly, adapted to an assembly package. As shown in FIG. 3, two substrate assemblies, taking the substrate assembly 1C as an example, are bonded with each other, with the first surfaces S1 of each of the substrates 20 of the substrate assembly 1C facing each other. The bonding may or may not occur through a bonding layer 30X (in this case, using an example with a bonding layer), to form a substrate structure 3 after bonding (as shown in FIG. 3X). The substrate assembly 3 can further have through holes 70xv formed through the substrates 20 of the two substrate assemblies 1C and bonding layer 30X (as shown in FIG. 3Y), and form a plurality of conductive vias 70x after filling with conductive material to electrically connect at least the first electrical layer structures 50 of the two substrate assemblies 1C; the conductive vias 70x can also further communicate with the second surfaces S2 of the two substrate assemblies 1C, as shown in FIG. 3; the conductive vias 70x can also further electrically connect to the second electrical layer structures 60 of the two substrate assemblies 1C, if the second electrical layer structures 60 are present. The bonding layer 30X includes inorganic material and/or organic material, such as silica (SiO₂), glass, ceramics, or polyimide, or combinations of one or more of the above materials. The bonding layer 30X includes glass frit, glass powder, glass paste, or combinations of one or more of the above materials. A thermal conductivity of the bonding layer is not less than a thermal conductivity of the substrates 20 of the two substrate assemblies 1C; furthermore, the thermal conductivity of the bonding layer 30X is not less than twice the thermal conductivity of the substrate 20. The bonding layer 30X may be or include a non-conductive thermal conductive layer, including non-conductive thermally conductive materials and/or thermally conductive particles; the thermal conductive layer includes thermally conductive materials of carbon nanotube and/or graphene, or a plurality of thermally conductive particles of silicon carbide (SiC) and/or silicon (Si). As shown in FIG. 3A, the bonding layer structure 30XA may be or include a conductive thermal conductive layer, including conductive thermally conductive materials and/or thermally conductive particles; the thermal conductive layer can be insulated from the through holes 70xv, wherein the insulation is achieved by the thermal conductive layer does not reach the through holes 70xv; the thermal conductive layer is a metal layer, or includes a plurality of metal particles. It can be understood that, in FIGS. 3 and 3A, the bonding layer is shown as a thermal conductive layer; while as shown in FIG. 3B as an example, the bonding layer can be formed as a composite structure, which can be referred to as a bonding layer structure 30XB, including a bonding layer 30XB1 and two thermal conductive layers 30XB2 located between the bonding layer 30XB1 and the upper and lower substrates 20 respectively; when the thermal conductive layers 30XB2 are conductive, they are insulated from the through holes 70xv, and the insulation is achieved by the thermal conductive layers does not reach through holes 70xv.

The substrate assembly 3 can further undergo removal of carrier boards 10 of each substrate assembly 1C and dicing process to produce a plurality of cutting units 4A, as shown in FIG. 4; here, the processes of removing carrier board 10 and producing cutting units 4A can be performed in any order. As shown in FIG. 4A, an assembly package 400 includes an electrical board 90 and a portion of substrate assembly 4 (i.e., one or ones of the cutting units 4A) disposed on the electrical board 90. As shown in FIG. 4AX, an assembly package 400′ includes an electrical board 90, and a portion of the substrate structure 4 configured on the electrical board 90, wherein in the cutting unit 4AX, the edge(s) E20 of the substrate 20 approach (align as much as possible with) the edge(s) E10 of the carrier board 10. It can be understood that the electrical layer in substrate assembly 1C is a single electrical layer, which can also be replaced with the first and second electrical layer structures 50′, 60′ (electrical redistribution structures) as in substrate assembly 2. It can be understood that the embodiments of the functional material described herein can also be applied here, where the functional material can wrap around the edges of each substrate 20.

Referring to FIG. 5, a substrate assembly 5 (or called substrate structure combination) includes two substrate assemblies 2 bonded through a bonding layer 30X, wherein the first and second electrical layer structures 50′, 60′ (electrical redistribution structures) of one substrate assembly 2 and the first and second electrical layer structures 50y, 60y (electrical redistribution structures) of the other substrate assembly 2 respectively have maximum line widths P50, P60, P50y, P60y, which can be arranged from small to large; in this embodiment, the carrier boards 10 have been removed from substrate assembly 5. It can be understood that the conductive vias 70y, similar to the various embodiments described above, can at least electrically connect the two electrical layer structures 50′, 50y of the two substrate assemblies, or further communicate with two corresponding second surfaces S2 of the two substrate assemblies, or can further electrically connect two corresponding second electrical layer structures 60′, 60y of the two substrate assemblies. The substrate assembly 5 can further undergo dicing process to produce a plurality of cutting units 5A; continuing to refer to FIG. 5A, an assembly package 500 includes an electrical board 90 and a portion of substrate assembly 5 (i.e., the cutting unit or cutting units 5A) disposed on the electrical board 90. Similarly, the substrate structure 5 can be cut into a plurality of cutting units 5AX, referring to FIG. 5AX, according to the dimensions of substrate 20, where the edge(s) E20 of the substrate 20 in the cutting unit 5AX approach (align as much as possible with) the edge(s) E10 of the carrier board 10; that is, an assembly package 500′includes an electrical board 90, and a portion of the substrate structure 5 (i.e., the cutting unit(s) 5A′) configured on the electrical board 90.

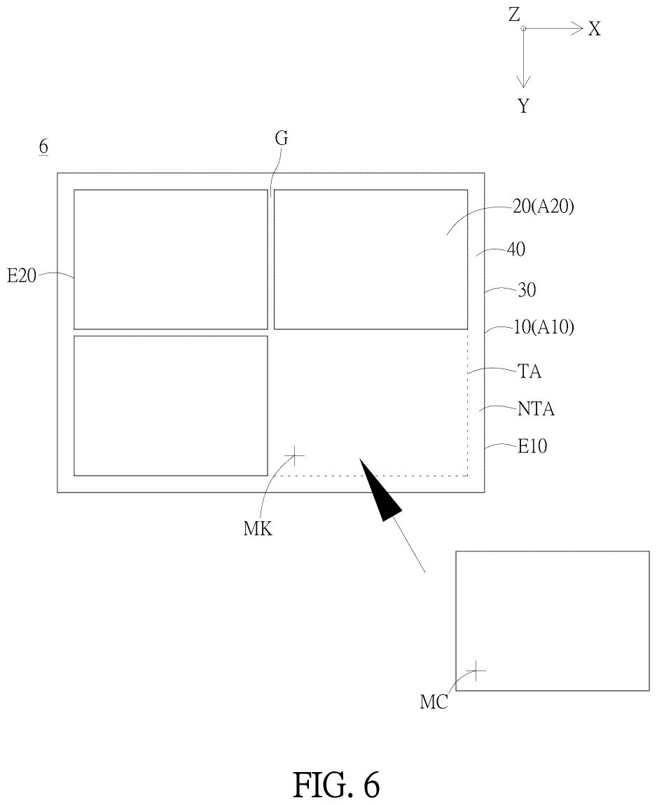

As shown in FIG. 6, another embodiment of the substrate structure 6 disclosed in this document differs from the substrate structure 1 in FIG. 1 in that substrate structure 6 includes one or more marks MK. These marks MK are disposed on the carrier substrate 10 and can be optical marks, physical marks, mechanical marks, or other forms of marks used for positioning, alignment, or identification. The positions of these marks MK are precisely designed and can be located in the non-tiling area NTA of the carrier substrate 10, providing a basis for alignment when the substrates 20 are tiled onto the carrier substrate 10 along the vertical direction Z. The positions of these marks MK can also be in the tiling area TA of the carrier substrate 10, with at least one mark MK′ located, along the vertical direction Z, within a projection range of one of the substrates 20 on the carrier substrate. Moreover, the substrate 20 itself may possess light-transmissive characteristics, meaning that light can pass through the substrate 20, which is relatively important in certain applications such as display devices, optical components, or photosensitive elements. It is worth noting that in embodiments with marks, the substrate 20 is not required to have light-transmissive characteristics. In some embodiments, the substrate structure 6 further includes one or more counter marks MC configured on the substrates 20. Similarly, these counter marks MC can also be optical marks, physical marks, mechanical marks, or other forms of marks. The aforementioned counter marks MC can form a paired relationship with the marks MK on the carrier substrate for precise alignment between the substrate 20 and the carrier substrate 10, determining whether the substrate 20 is correctly placed or needs adjustment. In this embodiment, substrates 20 with light-transmissive characteristics can further improve the accuracy of tiling and bonding, as well as manufacturing efficiency and product quality

The substrate assembly of the present invention is to provide a large-sized substrate that can be subsequently cut into “smaller-sized high-performance substrates” used for various advanced packaging. As we know some high-performance substrates may be limited by substrate size constraints and cannot undergo large-scale conductive circuit processing, resulting in high manufacturing costs. Therefore, in the present invention, substrates can be assembled on a carrier board to form a larger tiled substrate, then conductive circuit processing can be performed on this tiled substrate, followed by dividing it according to the required dimensions of high-performance substrates needed for subsequent advanced packaging use, thereby meeting both requirements of high-performance substrates and cost reduction effects.

Based on the above description, it should be understood that various embodiments of the present invention have been described in the specification for illustrative purpose, and various modifications can be made without departing from the scope and spirit of the present invention. Therefore, the various embodiments of the present invention are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. A substrate assembly, comprising:
a flexible substrate;
a carrier board, defining a planar direction;
a plurality of substrates adjacently arranged on the carrier board in the planar direction; each of the substrates defining a first surface and a second surface opposite to each other;
a temporary adhesive layer arranged between the carrier board and the second surface of each of the substrates; and
a functional material arranged between adjacent two of the substrates;
wherein planar area of the carrier board is not smaller than the sum of the planar areas of the substrates;
wherein in a direction perpendicular to the planar direction, a height difference is defined between the first surfaces of adjacent two of the substrates, and/or between the second surfaces of adjacent two of the substrates, and the height difference is not greater than 50 μm.

2. The substrate assembly of claim 1, wherein the carrier board and/or the substrates include Si, silica (SiO₂), glass, quartz, silicon carbide, ceramics, glass-ceramic, sapphire (Al₂O₃), compound semiconductor material, or polyimide, or any combination including one or more of the aforementioned materials.

3. The substrate assembly of claim 1, wherein the carrier board defines a coefficient of thermal expansion not greater than 15 ppm/K within a temperature range from 25° C. to 400° C.

4. The substrate assembly as claimed in claim 1, wherein the planar area of the carrier board in the planar direction is not less than 16000 mm².

5. The substrate assembly as claimed in claim 1, wherein a height difference is defined between the first surfaces of adjacent two of the substrates, and/or between the second surfaces of adjacent two of the substrates, and the height difference is not greater than 10 μm.

6. The substrate assembly as claimed in claim 1, wherein each of the substrates defines a flatness of not more than 10 μm on the first surface or the second surface.

7. The substrate assembly of claim 1, wherein the planar area of the carrier board is not less than twice of a planar area of the substrates.

8. The substrate assembly of claim 1, wherein the carrier board defines a thickness not greater than 1 mm.

9. The substrate assembly of claim 1, wherein the substrates defines a coefficient of thermal expansion not greater than 15 ppm/K within a temperature range from 25° C. to 40020 C.

10. The substrate assembly of claim 1, wherein each of the substrates is a multi-layer substrate, including a glass material, a glass-ceramic material, or a ceramic material, and a polyimide material bonded to the aforementioned material;
wherein a difference in coefficient of thermal expansion is defined between the polyimide material and the glass material/glass-ceramic material/ceramic material, and this difference in coefficient of thermal expansion is not greater than 5 ppm/K within a temperature range of 25°C.˜400° C.

11. The substrate assembly of claim 1, wherein each of the substrates defines a thermal conductivity coefficient not less than 1.0 W/m*K.

12. The substrate assembly of claim 1, wherein each of the substrates defines an elastic modulus not less than 50 GPa.

13. The substrate assembly of claim 1, further including a first electrical layer structure arranged on the first surface of each of the substrates.

14. The substrate assembly of claim 1, wherein each of the substrates include one or more conductive vias.

15. The substrate assembly of claim 1, wherein the height difference between the first surfaces of adjacent two of the substrates is not greater one-tenth of a thickness of adjacent one of the substrates.

16. The substrate assembly of claim 1, further including a first electrical layer structure and a second electrical layer structure, wherein the first electrical layer structure is arranged on the first surface of each of the substrates, the second electrical layer structure is arranged between the temporary adhesive layer and the second surface of each of the substrates; each of the substrates include one or more conductive vias electrically connecting the first electrical layer structure and the second electrical layer structure.

17. The substrate assembly of claim 1, wherein one or ones of the substrates defines a bending strength not less than 150 MPa (Megapascal).

18. The substrate assembly of claim 1, wherein one or ones of the substrates a dielectric loss Df (Loss Tangent) not greater than 0.006 at a test frequency of 10 GHz (Gigahertz).

19. The substrate assembly of claim 1, wherein the substrate assembly further defines a plurality of cutting units, wherein each of the cutting units is free of the gap.

20. The substrate assembly as claimed in claim 1, further including one or more marks, wherein the mark or marks are configured with the carrier substrate.

21. The substrate assembly of claim 1, wherein each of the substrate defines one or more the corners or edges, and one of the substrates defines a chamfer at one or ones of the corners or edges.

22. An assembly package, comprising a portion of a substrate assembly combination; wherein the substrate assembly combination includes two substrate assemblies of claim 1, the two substrate assemblies bonded with each other, and a conductive via at least electrically connecting the first electrical layer structures of the two substrate assemblies; wherein the portion of the substrate assembly combination, removed from the temporary adhesive layer and the carrier board, defines a plurality of cutting units, and each of the cutting units is free of the gap; the portion of the assembly package combination includes the cutting unit or the cutting units, wherein a size of each of the cutting units is greater than or equal to a size of one of the substrates, referred in the substrate assembly.

23. An assembly package, comprising:
a substrate defining a first surface and a second surface corresponding to each other, a plurality of corners or edges, one or more chamfers, and a plurality of conductive holes; and
a functional material arranged on at least a portion of the first surface and second surface of the substrate, and the corners or edges;
wherein the conductive holes communicate with at least one surface of the first and second surfaces of each substrate.
